(19) United States
(12) Patent Application Publication
(10) Pub. No.: US 2007/0245553 A1
(43) Pub. Date: Oct. 25, 2007

(54) FINE PITCH MICROFABRICATED SPRING CONTACT STRUCTURE & METHOD

(76) Inventors: Fu Chiung CHONG, Saratoga, CA (US); Roman L. Milter, Alviso, CA (US); Thomas Edward Dinan, San Jose, CA (US); Elaine McGee, San Jose, CA (US); W. R. Bottoms, Palo Alto, CA (US)

Correspondence Address: GLENN PATENT GROUP, 3475 EDISON WAY, SUITE L, MENLO PARK, CA, 94025, US

(21) Appl. No.: 11/692,138

(22) Filed: Mar. 27, 2007

Related U.S. Application Data
(63) Continuation-in-part of application No. 11/555,603, filed on Nov. 1, 2006.
Application No. 11/555,603 is a continuation of application No. 11/327,728, filed on Jan. 5, 2006, now Pat. No. 7,138,818.
Application No. 11/327,728 is a continuation of application No. 10/918,511, filed on Aug. 12, 2004, now Pat. No. 7,009,412.
Application No. 10/918,511 is a division of application No. 09/979,551, filed on Nov. 21, 2001, now Pat. No. 6,812,718.
(63) Continuation-in-part of application No. 10/932,552, filed on Sep. 1, 2004, now Pat. No. 7,247,035.
Application No. 10/932,552 is a continuation-in-part of application No. 10/069,902, filed on Jun. 28, 2002, now Pat. No. 6,791,171.
(63) Continuation-in-part of application No. 11/556,134, filed on Nov. 2, 2006.
Application No. 11/556,134 is a continuation of application No. 10/390,988, filed on Mar. 17, 2003, now Pat. No. 7,126,220.
Application No. 11/556,134 is a continuation of application No. 10/390,994, filed on Mar. 17, 2003, now Pat. No. 7,137,830.
(63) Continuation-in-part of application No. 11/133,021, filed on May 18, 2005.
(63) Continuation-in-part of application No. 10/870,095, filed on Jun. 16, 2004.
Application No. 10/870,095 is a continuation-in-part of application No. 10/178,103, filed on Jun. 24, 2002, now Pat. No. 6,917,525.
Application No. 10/178,103 is a continuation-in-part of application No. 09/980,040, filed on Nov. 27, 2001, now Pat. No. 6,799,976.
(60) Provisional application No. 60/787,473, filed on Mar. 29, 2006.
(60) Provisional application No. 60/810,037, filed on May 31, 2006.
(60) Provisional application No. 60/136,637, filed on May 27, 1999.
(60) Provisional application No. 60/213,729, filed on Jun. 22, 2000.
(60) Provisional application No. 60/365,625, filed on Mar. 18, 2002.
(60) Provisional application No. 60/365,625, filed on Mar. 18, 2002.
(60) Provisional application No. 60/573,541, filed on May 20, 2004.
(60) Provisional application No. 60/592,908, filed on Jul. 29, 2004.
(60) Provisional application No. 60/146,241, filed on Jul. 28, 1999.

(51) Int. Cl. H05K 3/00; H01R 43/16

(52) U.S. Cl. 29/843; 439/81; 439/66; 29/884

(57) ABSTRACT

An enhanced microfabricated spring contact structure and associated method comprises improvements to spring structures above the substrate surface, and/or improvements to structures on or within the substrate. Improved spring structures and processes comprise embodiments having selectively formed and etched, coated and/or plated regions, which are preferably further processed through planarization and/or annealment. Improved substrate structures and processes typically comprise the establishment of a decoupling structure on at least one surface of the substrate, and electromechanical fulcrum connections between elastic core members, e.g. stress metal springs, through defined openings in the decoupling structure toward electrically conductive pathways in the support substrate.

### CROSS REFERENCE TO RELATED APPLICATIONS

This application claims priority to U.S. Provisional Application No. 60/787,473, entitled Fine Pitch Microfabricated Spring Contacts, filed 29 Mar. 2006, and to U.S. Provisional Application No. 60/810,037, entitled Stress Metal Spring with Interface Stress Decoupling Layer, filed 31 May 2006.

This application is also a Continuation In Part of U.S. patent application Ser. No. 11/555,603, filed 1 Nov. 2006, which is a Continuation of U.S. application Ser. No. 11/327,728, entitled Massively Parallel Interface for Electronic Circuit, filed 5 Jan. 2006, issued as U.S. Pat. No. 7,138,818 on 21 Mar. 2006, which was a Continuation of U.S. application Ser. No. 10/918,511, filed 12 Aug. 2004, issued as U.S. Pat. No. 7,009,412 on 7 Mar. 2006, which is a Division of U.S. application Ser. No. 09/979,551, issued as U.S. Pat. No. 6,812,718, on 2 Nov. 2004, which was a National Stage Entry of PCT/US00/14768, parent or 371(c) date of 26 May 2000 and claims priority of U.S. Provisional Patent Application Ser. No. 60/136,637 filed on 27 May 1999.

This application is also a Continuation In Part of U.S. patent application Ser. No. 10/932,552, filed 1 Sep. 2004, which is a Continuation-in-part of U.S. patent application Ser. No. 10/069,902, filed 28 Jun. 2002, issued as U.S. Pat. No. 6,791,171 on 14 Sep. 2004, which claims priority to International Patent Application No. PCT/US01/19792 filed 20 Jun. 2001, which claims priority from U.S. Provisional Patent Application Ser. No. 60/212,923 filed 20 Jun. 2000, and U.S. Provisional Patent Application Ser. No. 60/213,729 filed 22 Jun. 2000.

This application is also a Continuation In Part of U.S. patent application Ser. No. 11/556,134, filed 2 Nov. 2006, which is a Continuation of U.S. patent application Ser. No. 10/390,988, issued as U.S. Pat. No. 7,126,220 on 24 Oct. 2006, which claims priority from U.S. Provisional Application No. 60/365,625, filed 18 Mar. 2002.

U.S. patent application Ser. No. 11/556,134, filed 2 Nov. 2006, is also a Continuation of U.S. application Ser. No. 10/390,994, filed 17 Mar. 2003, issued as U.S. Pat. No. 7,137,830 on 21 Nov. 2006, which claims priority from U.S. Provisional Application No. 60/365,625, filed 18 Mar. 2002.

This application is also a Continuation In Part of U.S. patent application Ser. No. 11/133,021, entitled High Density Interconnect System Having Rapid Fabrication Cycle, filed 18 May 2005, which claims priority to U.S. Provisional Application No. 60/573,541, entitled Quick-Change Probe Chip, filed 20 May 2004; U.S. Provisional Application No. 60/592,908, entitled Probe Card Assembly with Rapid Fabrication Cycle, filed 29 Jul. 2004; and U.S. Provisional Application No. 60/651,294, entitled Nano-Contactor Embodiments for IC Packages and Interconnect Components, filed 8 Feb. 2005.

U.S. patent application Ser. No. 11/133,021, entitled High Density Interconnect System Having Rapid Fabrication Cycle, filed 18 May 2005, is also a Continuation In Part of U.S. patent application Ser. No. 10/870,095, entitled Enhanced Compliant Probe Card Systems Having Improved Planarity, U.S. Filing Date 16 Jun. 2004, which is a Continuation In Part of U.S. patent application Ser. No. 10/178,103, entitled Construction Structures and Manufacturing Processes for Probe Card Assemblies and Packages Having Wafer Level Springs, US Filing Date 24 Jun. 2002, issued as U.S. Pat. No. 6,917,525 on 12 Jul. 2005, which is a Continuation In Part of U.S. patent application Ser. No. 09/980,040, entitled Construction Structures and Manufacturing Processes for Integrated Circuit Wafer Probe Card Assemblies, US Filing Date 27 Nov. 2001, which claims priority from PCT Patent Application Serial No. PCT/US00/21012, filed Jul. 27, 2000, which claims priority from U.S. Provisional Application No. 60/146,241, filed on 28 Jul. 1999.

Each of the aforementioned documents is incorporated herein in its entirety by this reference thereto.

### FIELD OF THE INVENTION

The present invention relates generally to the field of miniaturized spring contacts and spring probes for high density electrical interconnection systems. More particularly, the present invention relates to microfabricated spring contact methods and apparatus, and improvements thereto, for making electrical connections between semiconductor integrated circuits (ICs) having increasingly higher density and finer pitch input/output connections and the next level of interconnect in applications including but not limited to semiconductor device testing and packaging.

### BACKGROUND OF THE INVENTION

Advances in semiconductor integrated circuit design, processing, and packaging technologies have resulted in increases in the number and density of input/output (I/O) connections on each die and as well as in an increase in the diameter of the silicon wafers used in device fabrication. With increasing numbers of I/O connections per die, the cost of testing each die becomes a greater and greater fraction of the total device cost. The test cost fraction can be reduced by either reducing the time required to test each die or by testing multiple die simultaneously.

Probe cards may be used to test single or multiple die simultaneously at the wafer level prior to singulation and packaging. In multiple die testing applications, the requirements for parallelism between the array of spring probe tips on the probe card and the semiconductor wafer become increasingly stringent since the entire array of spring probe tips are required to make simultaneous electrical contact over large areas of the wafer.

With each new generation of IC technology, the I/O pitch tends to decrease and the I/O density tends to increase. These trends place increasingly stringent requirements on the probe tips. Fine pitch probe tips are required to be smaller in width and length while continuing to generate the force required to achieve and maintain good electrical connections with the device under test. The force required to achieve a good electrical connection is a function of the processing history of the IC contact pad, such as but not limited to the manner of deposition, the temperature exposure profile, the metal composition, shape, surface topology, and the finish of the spring probe tip. The required force is also typically a function of the manner in which the probe tip “scrubs” the surface of the contact pad.

As the probe pitch decreases, the linear dimensions of the IC connection terminal contact areas also decreases leaving less room available for the probe tips to scrub. Additionally, the probes must be constructed to avoid damaging the passivation layer that is sometimes added to protect the underlying IC devices (typically 5-10 mm in thickness). Additionally, as the spring probe density increases, the width and length of the probes tends to decrease and the stress within the probe tends to increase, to generate the force required to make good electrical contact to the IC connection terminal contact areas.

There is a need for probe cards for fine pitch probing comprised of an array of spring probe contacts capable of making simultaneous good electrical connections to multiple devices on a semiconductor wafer under test in commercially available wafer probers using specified overdrive conditions over large areas of a semiconductor wafer and or over an entire wafer. To accomplish this, the array of spring probe contacts on the probe card should be co-planar and parallel to the surface of the semiconductor wafer to within specified tolerances such that using specified overdrive conditions, the first and last probes to touch the wafer will all be in good electrical contact with the IC device yet not be subject to over stressed conditions which could lead to premature failure. Additionally, any changes in the Z position, e.g. due to set or plastic deformation, or condition of the probe tips, e.g. diameter, surface roughness, etc., over the spring probe cycle life should remain within specified acceptable limits when operated within specified conditions of use, such as but not limited to overdrive, temperature range, and/or cleaning procedures.

Micro-fabricated spring contacts are potentially capable of overcoming many of the limitations associated with conventionally fabricated spring contacts, e.g. tungsten needle probes, particularly in fine pitch probing applications over large substrate areas. Micro-fabricated spring contacts can be fabricated using a variety of photolithography based techniques known to those skilled in the art, e.g. Micro-Electro-Mechanical Systems (MEMS) fabrication processes and hybrid processes such as using wire bonds to create spring contact skeletons and MEMs or electroplating processes to form the complete spring contact structure. Arrays of spring contacts can be either be mounted on a contactor substrate by pre-fabricating and transferring them (either sequentially or in mass parallel) to the contactor substrate or by assembling each element of the spring contact array directly on the contactor substrate using a wire bonder along with subsequent batch mode processes, e.g. electroplating, as disclosed in U.S. Pat. No. 6,920,689 (Khandros et al.), U.S. Pat. No. 6,827,584 (Mathieu et al.), U.S. Pat. No. 6,624,648 (Eldridge et al.); U.S. Pat. No. 6,336,269 (Eldridge et al.), U.S. Pat. No. 6,150,186 (Chen et al.), U.S. Pat. No. 5,974,662 (Eldridge et al.),U.S. Pat. No. 5,917,707 (Khandros et al.), U.S. Pat. No. 5,772,452 (Dozier et al.), and U.S. Pat. No. 5,476,211 (Khandros et al.).

Micro-fabricated spring contacts may be fabricated with variety of processes known to those skilled in the art. Exemplary monolithic micro-fabricated spring contacts may comprise stress metal springs having one or more layers of built-in or initial stress that are photolithographically patterned and fabricated on a substrate using batch mode semiconductor manufacturing processes. As a result, the spring contacts are fabricated en masse, and can be fabricated with spacings equal to or less than that of fine pitch semiconductor device electrical connection terminals or with spacings equal to or greater than those of printed circuit boards, i.e. functioning as an electrical signal space transformer.

Photolithographically patterned spring structures are particularly useful in electrical contactor applications where it is desired to provide high density electrical contacts which may extend over relatively large contact areas and which also may exhibit relatively high mechanical compliance in the normal direction relative to the contact area. Such electrical contactors are useful for applications including integrated circuit device testing (both in wafer and packaged formats), integrated circuit packaging (including singulated device packages, wafer scale packaging, and multiple chip packages) and electrical connectors (including board level, module level, and device level, e.g. sockets.

In addition to providing compliance in the direction normal to the contact plane, photolithographically patterned spring contacts also compensate for thermal and mechanical variations and other environmental factors. An internal stress gradient within the spring contact causes a free portion of the spring to bend up and away from the substrate to a lift height which is determined by the magnitude of the stress gradient. The stress gradient can be any of a gradient within the free portion and between the free portion and the substrate. An anchor portion remains fixed to the substrate and is electrically connected to a first contact pad on the substrate. The spring contact is made of an elastic material and the free portion compliantly contacts a second contact pad, thereby contacting the two contact pads. Variations in the internal stress gradient across the substrate surface can cause variations in spring contact lift height.

The ability to produce uniform stress gradients over large substrate areas depends on being able to controllably create a sequence of one or more thin layers of deposited metal, each having controlled levels of mechanical stress. Deposited films having internal stress gradients are characterized by a first layer having a first stress level, a series of intermediate layers having varying stress levels, and a last layer having a last stress. The magnitude of the internal stress gradient is determined by the difference in stress levels between each layer in the film. The curvature of a lifted spring is a function of the magnitude of the internal stress and/or stress gradient, geometrical factors, e.g. thickness, shape, and material properties, e.g. Young's modulus. After release from the substrate, the free portion of the spring deflects upward until the stored energy is minimized.

For a given curvature, thicker springs require a greater stress or range of stresses than do thinner springs. Thicker springs are preferred when higher forces at a given deflection are required. For example, in certain electrical contactor applications, it is desirable to fabricate spring contacts having a relatively high contact force and a high lift height to provide low electrical resistance and a high mechanical compliance range. The combination of relatively high force and relatively high lift height requires both a relatively high stress gradient and a relatively large range of stress within the deposited film. In other words, springs having relatively large forces and high lift heights typically are relatively thick and have relatively high magnitude internal stress gradients extending over a larger range of stresses.

The stress range is increased when the spring comprises at least one layer of high compressive stress and at least one layer of high tensile stress. There is an upper limit to the compressive and tensile stresses that a thin film can sustain without loosing mechanical integrity.

It would be advantageous to provide a method and structure to create improved microfabricated spring contacts either directly or indirectly across the surface of substrate areas, which can provide increased strength and planarity over a wide variety of operating conditions. Such a development would provide a significant technical advance.

As well, it would also be desirable to provide a method and structure for decoupling stresses between microfabricated spring members and support substrates to provide relief of temperature induced stresses due to thermal expansion coefficient mismatches between the microfabricated springs and the support substrate. Such an improvement would enable the fabrication of springs of smaller size and finer pitch capable of operating over wider temperature ranges and would therefore constitute a further significant technical advance.

### SUMMARY OF THE INVENTION

An enhanced micro-fabricated spring contact structure and associated method comprises improvements to spring structures above the substrate surface, and/or improvements to structures on or within the substrate. Improved spring structures and processes comprise embodiments having selectively formed and etched, coated and/or plated regions, which are preferably further processed through a mechanically constrained heat treatment, such as but not limited to planarization and/or annealment. Improved substrate structures and processes typically comprise the establishment of a decoupling structure on at least one surface of the substrate, and electromechanical fulcrum connections between elastic core members, e.g. stress metal springs, through defined openings in the decoupling structure toward electrically conductive pathways in the support substrate.

### BRIEF DESCRIPTION OF THE DRAWINGS

FIG. 1 is a schematic view of an exemplary probe card assembly for testing single die on a silicon wafer;

FIG. 2 is a schematic side view of an exemplary contactor assembly comprising an array of compliant micro-fabricated spring contacts;

FIG. 3 is a detailed partial cross sectional view of an interposer structure;

FIG. 4 is a partial cross sectional view of a spring extending from a substrate and comprising one or more plating layers;

FIG. 5 is a detailed partial cross sectional view of a spring extending from a substrate and comprising one or more plating layers;

FIG. 6 is a flowchart of a process for forming a multiple plated spring having a plated tip area;

FIG. 7 is a detailed partial cutaway view of a multiple plated spring having a plated tip area;

FIG. 8 is a partial top view of a multiple plated spring having a plated tip area;

FIG. 9 is a flowchart of a process for forming a multiple plated spring having a double button structure;

FIG. 10 is a partial cutaway view of a multiple plated spring having a double button tip structure;

FIG. 11 is a detailed partial cutaway view of a multiple plated spring having a double button tip structure;

FIG. 12 is a partial top view of a multiple plated spring having a double button tip structure;

FIG. 13 is a flowchart of a process for forming an etch-back tip micro-fabricated spring probe;

FIG. 14 is a partial cutaway view of a micro-fabricated spring probe having an etch-back tip structure;

FIG. 15 is a flowchart of a process for forming a spring having a formed tip button;

FIG. 16 is a partial cross sectional view of a spring having a formed flat contour tip button;

FIG. 17 is a partial top view of a spring having a formed flat contour tip button;

FIG. 18 is a partial cross sectional view of a spring having a formed mushroom contour tip button;

FIG. 19 is a partial top view of a spring having a formed mushroom contour tip button;

FIG. 20 is a flowchart of a process for forming a spring having an etched tip metal region;

FIG. 21 is a partial cross sectional view of a spring having a full round etched tip metal region;

FIG. 22 is a partial top view of a spring having a full round etched tip metal region;

FIG. 23 is a partial cross sectional view of a spring having a central strip etched tip metal region;

FIG. 24 is a partial top view of a spring having a central strip etched tip metal region;

FIG. 25 is a partial cutaway view of an exemplary spring extending from a substrate and comprising one or more plating layers, to be used as a work piece in a spring enhancement process;

FIG. 26 shows the electrodeposition of a photoresist layer on a plated spring work piece structure;

FIG. 27 shows the controlled exposure of a portion of photoresist layer on a plated spring work piece structure;

FIG. 28 shows the controlled development of an exposed portion of photoresist layer on a plated spring work piece structure;

FIG. 29 shows a partial etch back of a portion of at least one plating layer on a plated spring work piece structure;

FIG. 30 shows controllable plating of an etch back region on a plated spring work piece structure;

FIG. 31 shows the stripping of photoresist from a plated etch back plated spring work piece structure;

FIG. 32 is a partial cutaway view of an alternate spring structure having a partially etched back single plating layer, comprising a plated tip structure within the etch back region;

FIG. 33 is a schematic view of an exemplary planarization fixture;

FIG. 34 is a partial cross sectional view of a first exemplary embodiment of a stress decoupling structure for a formed spring;

FIG. 35 is a partial cross sectional view of a second exemplary embodiment of a stress decoupling structure for a formed spring;

FIG. 36 is a partial cross sectional view of a spring extending from a substrate having a decoupling surface structure, wherein the spring has an additively formed button;

FIG. 37 is a partial cross sectional view of a spring extending from a substrate having a decoupling surface structure, wherein the spring has an etched-back contact structure;

FIG. 38 is a partial cross sectional view of a spring extending from a substrate having a decoupling surface structure, wherein the spring has an continuous plating structure;

FIG. 39 is a flowchart for processing of release layers associated with decoupling structures;

FIG. 40 is a partial lateral cutaway view of a spring formed on a substrate having a decoupling surface structure, wherein the structure comprises a small PI opening;

FIG. 41 is a partial top view of springs formed on a substrate having a decoupling surface structure, wherein the structure comprises small PI openings;

FIG. 42 is a partial lateral cutaway view of a spring formed on a substrate having a decoupling surface structure, wherein the structure comprises a medium sized PI opening;

FIG. 43 is a partial top view of springs formed on a substrate having a decoupling surface structure, wherein the structure comprises medium sized PI openings;

FIG. 44 is a partial lateral cutaway view of a spring formed on a substrate having a decoupling surface structure, wherein the structure comprises a large PI opening;

FIG. 45 is a partial top view of a springs formed on a substrate having a decoupling surface structure, wherein the structure comprises a large PI opening;

FIG. 46 is a simulated schematic cross section of a probe spring coupled directly to a support substrate;

FIG. 47 is a is a simulated schematic cross section of a probe spring coupled by one or more support pads within a fulcrum region through a stress decoupling structure and to a support substrate;

FIG. 48 is a partial cross sectional view of an alternate exemplary embodiment of a stress decoupling structure for a formed spring; and

FIG. 49 is a partial cutaway view of an exemplary embodiment of multi-layer routing on the front and back side of a probe chip.

### DETAILED DESCRIPTION OF PREFERRED EMBODIMENTS

Micro-fabricated spring contacts may be fabricated with a variety of processes known to those skilled in the art. Exemplary monolithic micro-fabricated spring contacts may comprise stress metal springs that are photolithographically patterned and fabricated on a substrate using batch mode semiconductor manufacturing processes. As a result, the spring contacts are fabricated en masse, and can be fabricated with spacings equal to or less than that of semiconductor bonding pads or with spacings equal to or greater than those of printed circuit boards, i.e. functioning as an electrical signal space transformer.

Fabrication of high density arrays of spring contacts are also possible using monolithic micro-fabrication processes wherein arrays of elastic, i.e. resilient, core members, i.e. spring contact skeleton structures, are fabricated directly on a contactor substrate utilizing thick or thin film photolithographic batch mode processing techniques such as those commonly used to fabricate semiconductor integrated circuits.

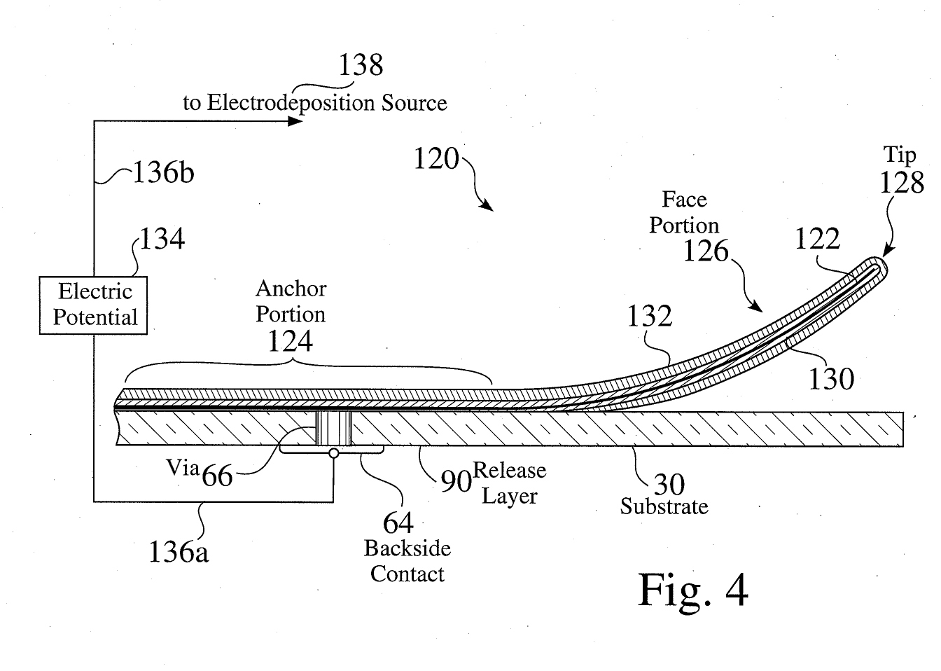

The spring constant of the spring is a function of the Young's modulus of the material used to fabricate the spring and the length, width, and thickness of the spring. The spring constant of the spring can be increased by enveloping the springs 40 with a coating of a metal including but not limited to electroplated, or sputtered, or CVD deposited nickel or a nickel alloy, gold, or a palladium alloy such as palladium cobalt (see FIG. 4).

The spring constant can be varied over many orders of magnitude by controlling the thickness of the deposited coating layer, the geometrical characteristics of the spring, and the choice of metal and the thickness and number of coatings. Making the springs thicker both increases the contact force and the robustness of the physical and electrical contact between the spring and its contact pad.

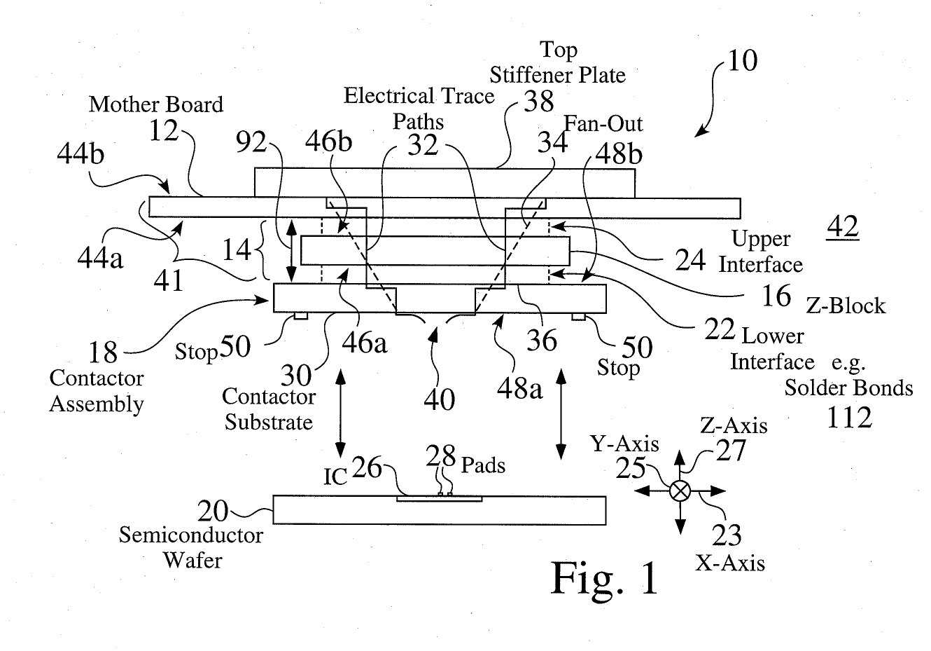

FIG. 1 is a detailed schematic diagram 10 of a probe card assembly 42. As seen in FIG. 1, the probe card assembly 42 comprises a probe card interface assembly (PCIA) 41 and a contactor assembly 18, wherein the probe card interface assembly (PCIA) 41 comprises a motherboard 12 having electrical connections 132 (FIG. 4) extending there through, and an integrated contactor mounting system 14. Electrical trace paths 32 extend through the motherboard 12, the contactor mounting system 14, and the contactor assembly 18, to spring contacts, i.e. spring probes 40, such as to establish contacts with pads 28 on one or more ICs 26 on a semiconductor wafer 20. Fan-out 34 may preferably be provided at any point for the electrical trace paths 32 in a probe card assembly 42 (or in other embodiments of the systems disclosed herein), such as to provide transitions between small pitch components or elements, e.g. contactors 18, and large pitch components or elements, e.g. tester contact pads 126 (FIG. 4) on the mother board 12. For example, fan-out may typically be provided by the mother board 12, the contactor 30, by a Z-block 16, by an upper interface 24 comprising a motherboard Z-Block, or anywhere within the lower interface 22 and/or the upper interface 24.

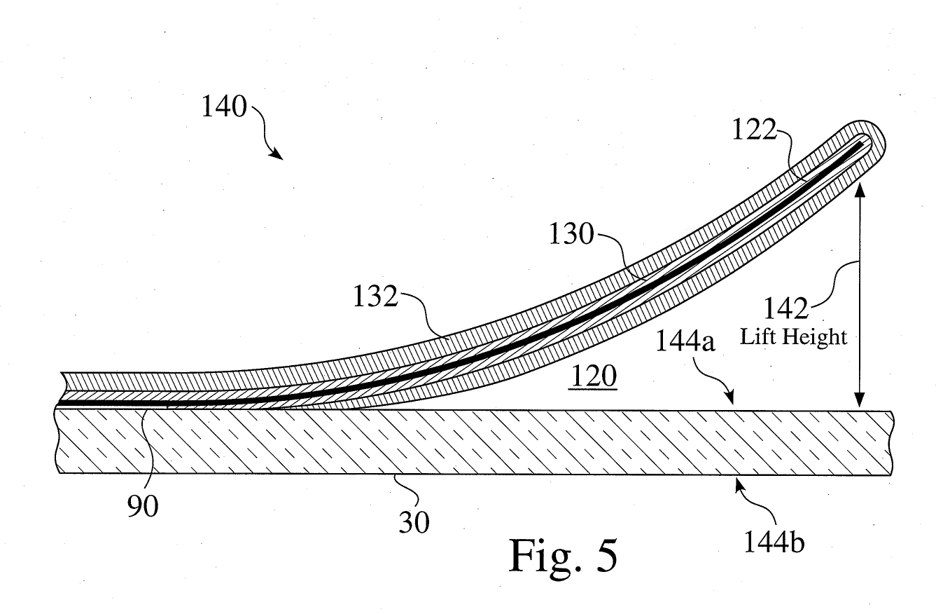

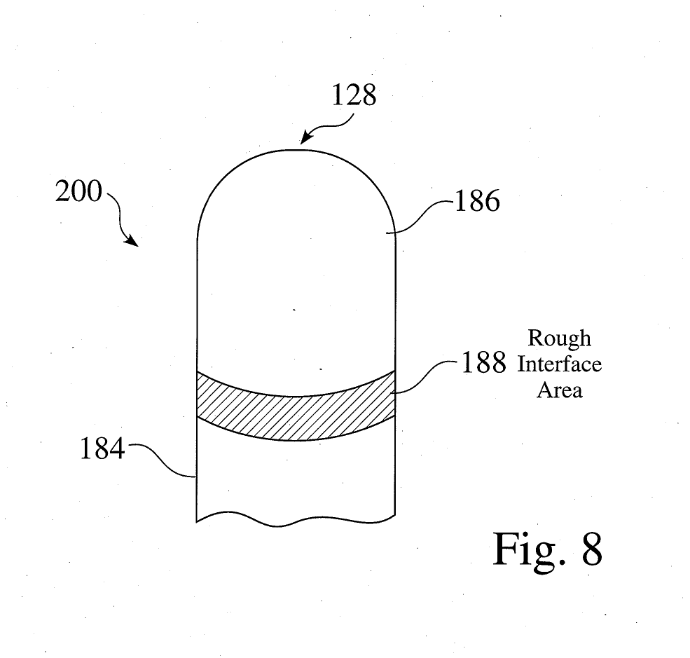

As seen in FIG. 1, the contactor mounting system 14 typically comprises a Z-block 16, a lower interface 22 between the Z-block 16 and the contactor substrate 30, and an upper interface 24 between the Z-block 16 and the motherboard 12. In some quick change probe card assemblies 42, the lower interface 22 comprises a plurality of solder bonds 112 (FIG. 4). As well, in some quick-change probe card assemblies 42, the upper interface 24 comprises a combination of componentry and connections, such as an interposer 122, e.g. 122a (FIG. 8) or 122b (FIG. 5), solder bonds and/or a motherboard Z-block.

Additionally, optical signals can be transmitted through the contactor substrate by fabricating openings of sufficient size through the substrate through which the optical signals can be transmitted. The holes may be unfilled or filled with optically conducting materials including but not limited to polymers, glasses, air, vacuum, etc. Lenses, diffraction gratings and other optical elements can be integrated to improve the coupling efficiency or provide frequency discrimination when desired.

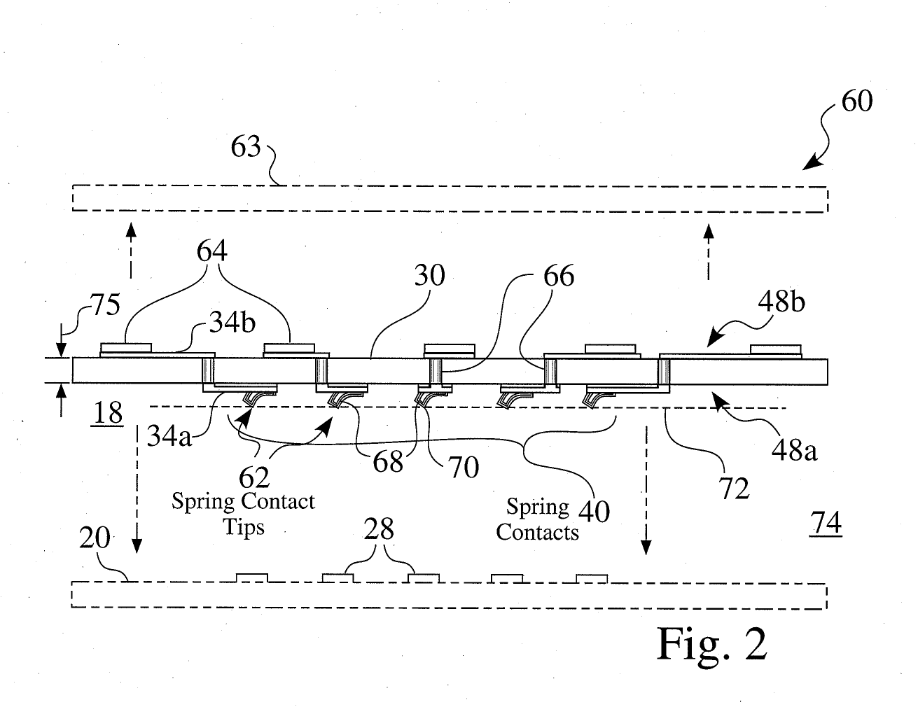

FIG. 2 is a detailed schematic view 60 of a contactor assembly 18, in which the non-planar portions of compliant spring probes 40 are preferably planarized and/or plated. As seen in FIG. 2, a contactor 18 comprises a contactor substrate 30 having a probing surface 48a and a bonding surface 48b opposite the probing surface 48a, a plurality of spring probes 40 on the probing surface 48a, typically arranged to correspond to the bonding pads 28 (FIG. 1) of an integrated circuit 26 on a semiconductor wafer 20, and extending from the probing surface 48a to define a plurality of probe tips 62, a corresponding second plurality of bonding pads 64 located on the bonding surface 48b and typically arranged in the second standard configuration, and electrical connections 66, e.g. vias, extending from each of the spring probes 40 to each of the corresponding second plurality of bonding pads 64.

While the contacts 40 are described herein as spring contacts 40, for purposes of clarity, the contacts 40 may alternately be described as contact springs, spring probes or probe springs.

Preferred embodiments of the spring contacts 40 may comprise either non-monolithic micro-fabricated spring contacts 40 or monolithic micro-fabricated spring contacts 40, depending on the application. Non-monolithic micro-fabricated spring contacts utilize one or more mechanical (or micro-mechanical) assembly operations, whereas monolithic micro-fabricated spring contacts utilize batch mode processing techniques including but not limited to photolithographic processes such as those commonly used to fabricate MEMs devices and semiconductor integrated circuits.

In some embodiments of the spring contacts 40, the electrically conductive monolithically formed contacts 40 are formed in place on the contactor substrate 30. In other embodiments of the spring contacts 40, the electrically conductive monolithically formed contacts 40 are formed on a sacrificial or temporary substrate 63, and thereafter are removed from the sacrificial or temporary substrate 63, e.g. such as by etchably removing the sacrificial substrate 63, or by detaching from a reusable or disposable temporary substrate 63, and thereafter affixing to the contactor substrate 30.

Both non-monolithic and monolithic micro-fabricated spring contacts can be utilized in a number of applications including but not limited to semiconductor wafer probe cards, electrical contactors and connectors, sockets, and IC device packages.

Sacrificial or temporary substrates 63 may be used for spring fabrication, using either monolithic or non-monolithic processing methods. Spring contacts 40 can be removed from the sacrificial or temporary substrate 63 after fabrication, and used in either free standing applications or in combination with other structures, e.g. contactor substrate 30.

In embodiments of contactor assemblies that are planarized, a plane 72 of optimum probe tip planarity is determined for a contactor 18 as fabricated. Non-planar portions of spring contacts 40 located on the substrate 30 are preferably plated 60, and are then planarized, such as by confining the probes 40 within a plane within a fixture, and heat treating the assembly. The non-planar portions of the spring probes 40 may also be plated after planarization, to form an outer plating layer 70.

The contactor assembly 18 shown in FIG. 2 further comprises fan-out 34, such as probe surface fan-out 34a on the probe surface 48a of the contactor substrate 18 and/or rear surface fan-out 34b on the bonding surface 48b of the contactor substrate 18.

Monolithic micro-fabricated spring contacts 40, such as seen in FIG. 2, comprise a unitary, i.e. integral construction or initially fabricated using planar semiconductor processing methods, whereas non-monolithic spring contacts are typically assembled from separate pieces, elements, or components. Non-monolithic or monolithic micro-fabricated spring contacts can be fabricated on one or both sides of rigid or flexible contactor substrates having electrically conductive through-vias and multiple electrical signal routing layers on each side of the substrate to provide electrically conductive paths for electrical signals running from spring contacts on one side of the substrate to spring contacts or other forms of electrical connection points on the opposite side of the substrate through signal routing layers on each side of the substrate and one or more electrically conductive vias fabricated through the substrate.

An exemplary monolithic micro-fabricated spring contact comprising a stress metal spring i.e. an elastic core member, is fabricated by sputter depositing a titanium adhesion/release layer having a thickness of 1,000 to 5,000 angstrom on a ceramic or silicon substrate (approximately 10-40 mils thick) having 1-10 mil diameter electrically conductive vias pre-fabricated in the substrate. Electrically conductive traces fabricated with conventional photolithographic processes connect the spring contacts to the conductive vias and to the circuits to which they ultimately connect. A common material used to fabricate stress metal springs is MoCr, however other metals with similar characteristics, e.g. elements or alloys, may be used. An exemplary stress metal spring contact is formed by depositing a MoCr film in the range of 1-5 mm thick with a built-in internal stress gradient of about 1-5 GPa/mm. An exemplary MoCr film is fabricated by depositing 2-10 layers of MoCr, each layer about 0.2-1.0 mm thick. Each layer is deposited with varying levels of internal stress ranging from up to 1.5 GPa compressive to up to 2 GPa tensile.

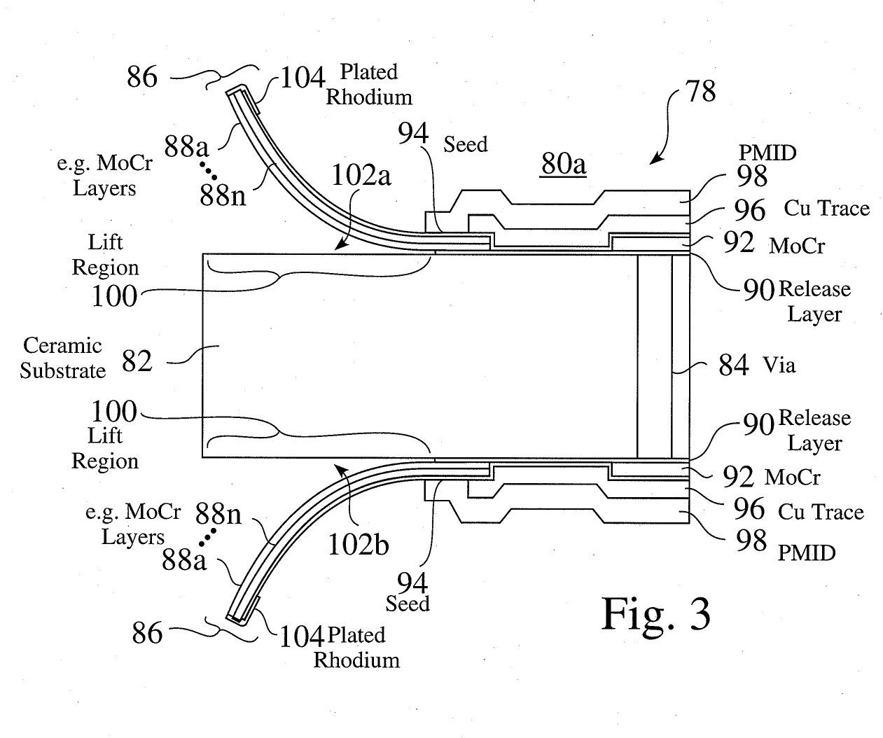

Individual micro-fabricated stress metal spring contact “fingers” are photolithographically patterned and released from the substrate, using an etchant to dissolve the release layer. The sheet resistance of the finger and its associated trace can be reduced by electroplating with a conductive metal layer (such as copper, nickel, or gold). The force generated by the spring contact can be increased by electrodepositing a layer of a material, such as nickel, on the finger to increase the spring constant of the finger. In interposer applications (see FIG. 3), the quality of the electrical contact can be improved by electrodepositing depositing a material, such as Rhodium 104, onto the tip 86 through a photomask, prior to releasing the finger from the substrate.

The lift height of the spring contacts is a function of the thickness and length of the spring and the magnitude of the stress gradient within the spring. The lift height is secondarily a function of the stress anisotropy and the width of the spring and the crystal structure and stress in the underlying stress metal film release layer. The spring constant of the spring is a function of the Young's modulus of the material used to fabricate the spring and the length, width, and thickness of the spring. The spring constant of the spring can be increased to the degree desired by enveloping the springs 40 with one or more electrodeposited, sputtered, or CVD metal coatings (see FIG. 1,2). Coatings can be applied with thicknesses of between 1 micron and 100 microns using metals including nickel, gold, palladium, platinum, rhodium, tungsten, cobalt, iron, copper, and combinations thereof. The spring constant can be varied by controlling the thickness of the deposited coating layers, the geometrical characteristics of the spring, the choice of metal, and the number of coatings.

The microstructure and hence mechanical properties of the resulting spring contacts are a function of the metals deposited as well as the deposition and subsequent processing conditions. The process conditions for fabricating spring contacts according to the present invention comprise, electrodeposition current densities in the range of about 0.3 to about 30 Amperes/square decimeter (typically 3 Amperes per square decimeter) and saccharine added at a concentration of greater than about 1 gram/liter or preferably greater than 4.5 grams per liter. One or more heat treatment processes are preferably included, such as to provide any of probe tip planarization relative to the support substrate and/or annealment to provide increased resistance to set and cracking through repeated cycles of deflection over the life of the spring contact.

Grain sizes for spring coating or plating layers, e.g. 130,132 (FIG. 4, FIG. 5), such as comprising nickel coatings 130,132 fabricated using the above conditions may typically range from about 200 nm to about 400 nm, e.g. as measured by SEM cross sections. but may range from as low as about 100 nm to about 500 nm before the anneal processing step. After the annealing processing step, the grain sizes typically grow to larger than about 400 nm, and may even exceed about 1000 nm.

It should be noted that methods for depositing coatings of both insulating and conductive materials are discussed in Yin et al., Scripta mater: 44(2001) 569-574; Feenstra, et al, Materials Science and Engineering: A, Volume 237, Number 2, September 1997, pp. 150-158(9); Kumar et al., Acta Materialia 51 (2003) 387-405), and patent applications, such as U.S. Pat. No. 6,150,186. Electrodeposited layers of metals such as nickel and nickel alloys such as Nickel Cobalt are characterized as having “nanocrystalline” microstructures when the grain sizes range from less than a few tens of nanometers to an extreme upper limit of 100 nm. From this description, the materials fabricated as described above would not be characterized as having nanocrystalline microstructures.

Setting, i.e. plastic deformation, of the probes during the useful life of the product can be minimized by carrying out an annealing process at an optimal time and temperature. For example, using a 250 C anneal temperature, it was observed that a minimum set occurred for a 3 hour anneal (5 microns) whereas for 1 hour and 12 hours annealing times, set was observed to be 28 microns and 12 microns respectively. Additionally, accelerated aging studies, i.e. repeated, cycling of the spring probes on a probe card using a wafer prober have shown that the spring contacts are resistant to cracking when fabricated with an anneal time selected to reduce set such as for the annealing process described above. However, it has also been observed that resistance to cracking decreases with anneal times in excess of that required to minimize set.

The above teachings describe the manufacture of an exemplary monolithic micro-fabricated stress metal spring, however, those skilled in the art will understand that spring contacts having the characteristics required to practice the present invention can provide many possible variations in design and/or fabrication processes. Such variations may include but would not be limited to, for example, choice of processes, process chemicals, process step sequence, base spring metal, release layer metal, coating metals, spring geometry, etc. The structures and processes disclosed herein may preferably be applied to a wide variety of non-monolithic spring contacts and monolithic micro-fabricated spring contacts, such as but not limited to spring structures disclosed in D. Smith and A. Alimonda, Photolithographically Patterned Spring Contact, U.S. Pat. No. 6,184,699; M. Little, J. Grinberg and H. Garvin, 3-D Integrated Circuit Assembly Employing Discrete Chips, U.S. Pat. No. 5,032,896; M. Little, Integrated Circuit Spring Contacts, U.S. Pat. No. 5,663,596; M. Little, Integrated Circuit Spring Contact Fabrication Methods, U.S. Pat. No. 5,665,648; and/or C. Tsou, S. L. Huang, H. C. Li and T. H. Lai, Design and Fabrication of Electroplating Nickel Micromachined Probe with Out-of-Plane Deformation, Journal of Physics: Conference Series 34 (2006) 95-100, International MEMS Conference 2006.

FIG. 3 is a partial cross sectional view 78 of an interposer structure 80, such as for a dual-sided interposer 80a, Similar construction details are preferably provided for a single-sided interposer.

Interposer springs 86, such as photolithographically formed probe springs 86, are generally arranged within an interposer grid array, to provide a plurality of standardized connections. For example, in the dual-sided interposer 80a shown in FIG. 4, the interposer springs 86 provide connections between a motherboard 12 and a Z-block 16. Similarly, in a single-sided interposer, the interposer springs 86 provide connections between a motherboard 12 and an interposer 80b.

Interposer vias 84 extend through the interposer substrate 82, from the first surface 102a to the second surface 102b. The interposer vias 84 may preferably be arranged in redundant via pairs, such as to increase the manufacturing yield of the interposer 80, and/or to promote electrical conduction, particularly for power traces.

The opposing surfaces 102a,102b are typically comprised of a release layer 90, such as comprising titanium, and a composite layer 88,92, typically comprising a plurality of conductive layers 88a-88n, having different inherent levels of stress. Interposer vias 84, e.g. such as CuW, PtAg, or gold filled, extend through the central substrate 82, typically ceramic, and provide an electrically conductive connection between the release layers 90. The composite layers 88,92 typically comprise MoCr (however other metals with similar characteristics, e.g. elements or alloys, may be used), in which the interposer probe springs 86 are patterned and subsequently to be later released within a release region 100.

In one embodiment, a seed layer 94, such as a 0.5 to 1 μm thick gold layer, is preferably formed over the composite layers 88,92. In some embodiments, a tip coating 104, such as rhodium or palladium alloy, is controllably formed at least over the tips of spring fingers 86, such as to provide wear durability and/or contact reliability. Traces 96, typically comprising copper (Cu), are selectably formed by plating over the structure 78, as shown, such as to provide reduced resistance. As well polyimide PMID layers 98 are typically formed over the structure 78, as shown, to define the spring finger lift regions. A seed layer 94, such as comprising a thick layer of gold, remains on the lifted fingers 86, to reduce sheet resistance of the fingers 86.

Multiple Plated Spring Structures. FIG. 4 is a partial cross sectional view of an enhanced spring contactor 120 extending from a substrate 30 and comprising one or more plating layers. FIG. 5 is a detailed partial cross sectional view 140 of an elastic spring element 122 for an enhanced spring contactor 120, that extends from a substrate 30 and comprising one or more plating layers.

As seen in FIG. 4 and FIG. 5, an elastic spring member 122 typically comprises one or more layers having different initial levels of stress, such as defined between the elastic member 122 and the release layer 90, or between at least two of layers 88 of the spring member 122. The elastic member 122 comprises a fixed portion 124 that extends to a face, i.e. non-planar portion 126, toward a tip region 128. The spring member 122 generally defines a lift height 142 from the surface of the substrate, e.g. substrate 30, from which it extends. The elastic spring member 122 typically comprises one or more layers 88a-88n of metal, e.g. molybdenum chromium (MoCr), i.e. molychome, having different initial layers of stress before release from the substrate they are formed upon, such as directly or indirectly upon a substrate 30, e.g. comprising ceramic.

Subsequent plating layers are also typically formed on the one or more elastic spring members 122, such as comprising a first structural layer 130, e.g. nickel (Ni) or nickel cobalt (NiCo) and a second structural layer 132, e.g. nickel (Ni) or nickel cobalt (NiCo).

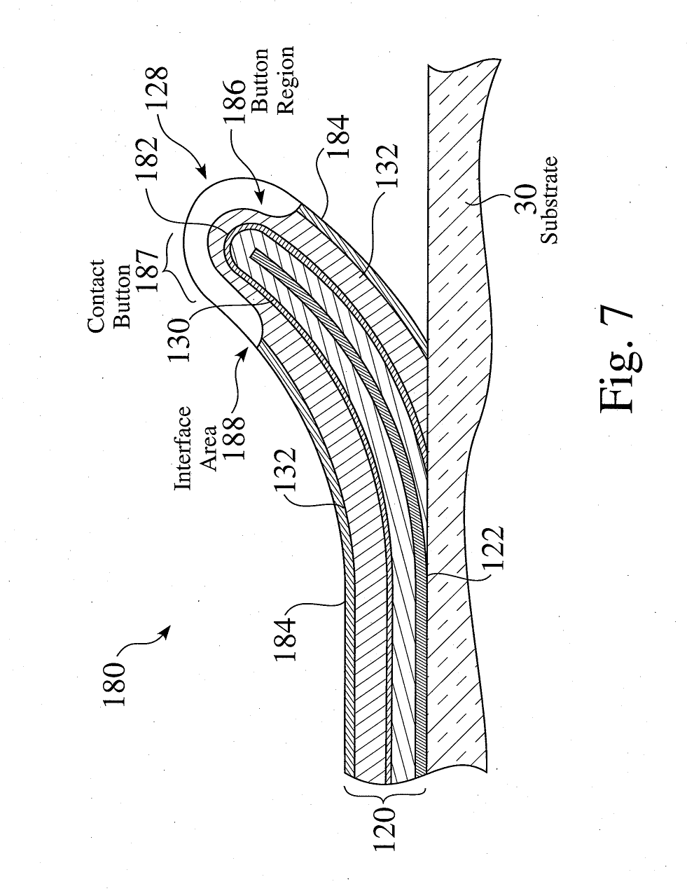

An adhesion layer 182 (FIG. 7), e.g. such as comprising gold, may be located between the structural layers, such as between the first structural layer 130 and the second structural layer 132. As well, an outer layer 184, e.g. such as nickel cobalt (NiCo) may preferably be formed on the second structural layer 132.

Micro-fabricated contactors, such as comprising the structure 120 seen in FIG. 4 and FIG. 5, may comprise a plurality of elastic core members 122, wherein each core member 122 typically has an anchor portion 124 attached to a substrate, e.g. 30, and a free portion 126, initially attached to the substrate 30, which upon release, extends to a tip lift height 142 away from the substrate 30, due to an inherent stress gradient in the respective core members 122.

Such core members 122 typically have their exposed surfaces enveloped with at least one electrodeposited metal coating layer, such as 130, 132, 182, and/or 184, such as without a mask on the elastic core member(s) 122, and typically using a backside contact, e.g. 66,68 as an electrode connected 136a to an electric potential source 134, which is also typically connected 136b, to an electrodeposition source, e.g. a plating bath 138. The electrodeposited layers are preferably deposited under specified conditions, to controllably achieve one or more of desired characteristics.

For example, one or more of the coating or plating layers minimize variations in tip lift heights 142 of each member 122 of a plurality of core members 122, such as relative to either the front or the back surface of the substrate 30, subsequent to a planarization process.

During a planarization process, the tips 128 of the plurality of core members 122 are constrained by a mechanical fixture at a fixed distance from either the front or the back surface of the substrate, and are then subjected to a controlled temperature cycle. The planarization process accelerates plastic deformation of each member 122 of the plurality of core members 122, preferably without causing delamination of any member 122 from the substrate 30, such as due to stresses generated by thermal shock or thermal coefficient of expansion mismatch between the substrate 30 and the anchor region 124 of the spring contacts.

In some embodiments of the enhanced spring contactor 120, one or more of the coating or plating layers provide sufficient force, such as at a specified wafer prober overdrive, to insure good electrical contact to the electrical connection terminals of the device under test over the useful life of the spring contacts 122.

In some embodiments of the enhanced spring contactor 120, one or more of the coating or plating layers are designed to minimize changes in the tip lift height due to set while resisting cracking of any of the members of the plurality of core members 122 over the operating temperature range and useful life of the spring contact 122, such as subsequent to an annealing process at a specified time and temperature designed to promote grain growth and at least partial internal stress relief without causing delamination of any member of the plurality of elastic core members 122 from the substrate 30, due to stresses generated by thermal shock or thermal coefficient of expansion mismatch between the substrate 30 and the anchor region 124 of the spring contacts 122.

In some embodiments of the enhanced spring contactor 120, one or more of the coating or plating layers are designed to lower the electrical resistance through each member of the plurality of core members 122, and/or to provide a low contact resistance to the electrical connection points of a device under test at a specified overdrive during operation.

In some embodiments of the enhanced spring contactor 120, one or more of the coating or plating layers, e.g. 130, 132, 182, and/or 184, comprise electrodeposited metal coatings that are fabricated to a thickness of between 1 micron and 100 microns, such as using metals selected from the group comprising any of nickel, gold, palladium, platinum, rhodium, tungsten, cobalt, iron, copper, and combinations thereof.

In some embodiments of the enhanced spring contactor 120, one or more of the coating or plating layers, e.g. 130, 132, 182, 184, comprise electrodeposited metal coatings that are fabricated under specified electrodeposition conditions to cause diffusion limited transport of the depositing species and, optionally, by the addition of additives such as saccharine at a concentration of greater than about 1 gram/liter or preferably greater than 4.5 grams per liter, produce a plated metal layer, optionally, with an inherent compressive stress.

For example, a typical electrodeposition current density for some layers, such as but not limited to Ni and NiCo, is about 3 amperes per square decimeter, but may range from about 0.3 to about 30 amperes per square decimeter. In some embodiments, the typical electrodeposition conditions for PdCo range from about 0.3 to about 0.5 amperes per square decimeter. In some embodiments, the typical deposition conditions for Rhodium are about 1 ampere per square decimeter.

In some embodiments of the enhanced spring contactor 120, the temperature cycle of the planarization process comprises:
a ramp up time ranging from about 15 minutes to about 2 hours;
a dwell time of about 10 minutes to about 2 hours, depending on the planarization temperature which ranges from about 180 C to about 300 C or preferably from about 185 C to about 275 C; and
a ramp down time of about 15 minutes to about 6 hours.

In some embodiments of the enhanced spring contactor 120, at least one of the coating or plating layers, e.g. 130, 132, 182, 184, generates a force ranging from about 0.5 gram to about 15 grams at wafer prober overdrives ranging from about 15 microns to about 100 microns.

Some embodiments of the enhanced spring contactor 120 may also preferably be annealed, wherein the annealing process conditions comprise:
a ramp up time ranging from about 15 minutes to about 2 hours;
a dwell time ranging from about 10 minutes to about 60 hours depending on the annealing temperature which ranges from about 180 C to about 300 C or preferably from about 185 C to about 275 C; and
a ramp down time of about 15 minutes to 6 hours, to cause grain growth from about 0.05-0.3 mm to about 0.5-1.2 mm.

In some embodiments of the enhanced spring contactor 120, at least one of the coating or plating layers, e.g. 130, 132, 182, 184, provides an electrical resistance through each member of the plurality of core members of less than about 2 ohms.

In some embodiments of the enhanced spring contactor 120, one or more of the coating or plating layers, e.g. 130, 132, 182, 184, preferably provide any of a contact resistance to the electrical connection points or terminals of a device under test at less than about 2 ohms; and/or a robust low resistance electrical connection to the device connection terminals.

In some embodiments of the enhanced spring contactor 120, one or more of the coating or plating layers, e.g. 130, 132, 182, 184, are deposited without a mask, by supplying plating current from the back of the substrate 30 through a via contact 66 through the substrate 30, and enveloping all exposed surfaces of the underlying spring contacts 122, and optionally, without any discontinuities.

In some embodiments of the enhanced spring contactor 120, one or more of the coating or plating layers, e.g. 130, 132, 182, 184, are electrodeposited through a mask, such as a mask that covers at least a portion of the spring contact tip extending from the tip 128 toward the anchor portion 124, the mask formed from any of spray coated photo resist, spin coated photo resist, and electrodeposited photo resist.

An exemplary process for forming some embodiments of the enhanced spring contactor 120 typically the step of providing a structure comprising a contactor substrate 30 having a front surface 142a and a back surface 142b, wherein the contactor substrate 30 comprises at least one electrically conductive microfabricated spring contact 122 located on and extending from the front surface 144a of the substrate 30 to a initial lift height 144 relative to either the back surface 144b or front surface 144a of the contactor substrate 30.

At least one layer of metal, e.g. 130, 132, 182, 184, is then typically electrodeposited on the spring contacts 122, such as by enveloping the spring contacts 122, to provide low electrical resistance paths through the springs 122, and low resistance electrical contacts to a metal surface placed in physical contact with spring contact tip 128, such as at a predetermined deflection of the spring contacts 122, and/or to provide a specified force at a specified deflection.

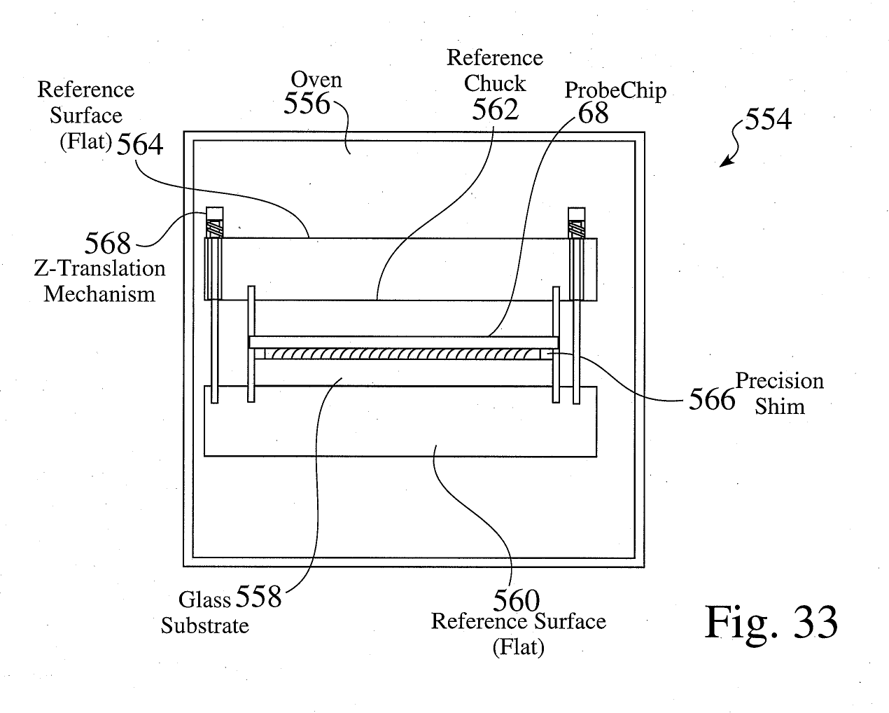

The contactor substrate 30 is then preferably mounted in a mechanical fixture 554 (FIG. 33), to compressing the spring contacts 122 against a reference surface 560 to a distance from either the front surface 144a or the back surface 144b of the substrate 30. The distance is determined the mechanical fixture 554, and thereby induces stress into the spring contacts 122. Within the mechanical fixture, the spring contacts 122 are compressed, such that the spring tip heights 144 are essentially equal.

The contactor substrate 30 is then preferably planarized to induce plastic deformation within the layers of electrodeposited metal, e.g. 130, 132, 182, 184, to cause the working lift height 142 to be determined by a mechanical fixture 554 (FIG. 33).

The spring contacts 122 may also preferably be annealed, e.g. such as by heating the assembly to a predetermined temperature for a predetermined time, such as to cause grain growth and/or at least partial stress relief in the layers of the electrodeposited metal.

Heating of the structure to a predetermined temperature for a predetermined time may preferably provide any of:
plastic deformation in the spring contacts 122, such as to minimize variations in tip height 142, typically relative to either the back surface 144b or the front surface 144a of the contactor substrate; and/or
increased resistance to set and/or cracking through repeated cycles of deflection, such as to thereby extend the useful life of each member of the plurality of spring contacts 122.

The mechanical fixture 554 used for any of the planarization and the annealing steps may preferably comprise means for determining the spring compression distance from the substrate 30, such as comprising any of a fixed spacer, an adjustable spacer, a shim, a stencil, a fabricated mechanical reference, and at least one precision screw adjustment.

The exemplary planarization and or annealing processes are described in regard to the structures seen in FIG. 4 and FIG. 5, wherein the microfabricated spring contacts 122 typically comprise an anchor portion 122 attached to the front surface 144a of the substrate 30, either directly, or indirectly through to one or more layers located on the front surface 144a of the substrate 30, and a free portion 126, initially attached, e.g. to the substrate 30, which upon release, extends to a initial lift height away from the substrate 30, due to an inherent stress gradient in the spring contacts 122.

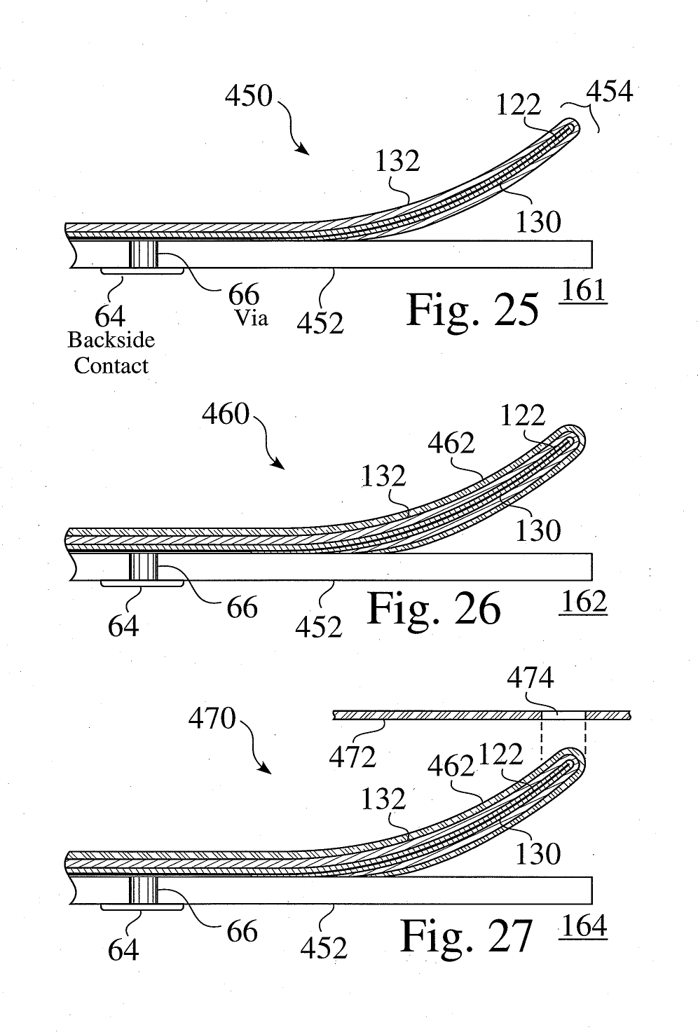

While the exemplary planarization and or annealing processes are described in regard to the structures seen in FIG. 4 and FIG. 5, the planarization and or annealing processes can alternately be applied to a wide variety of spring structures, such as but not limited to contactor embodiments described below that comprise decoupling substrates 610 (FIG. 25,FIG. 26) located on a support substrate 30.

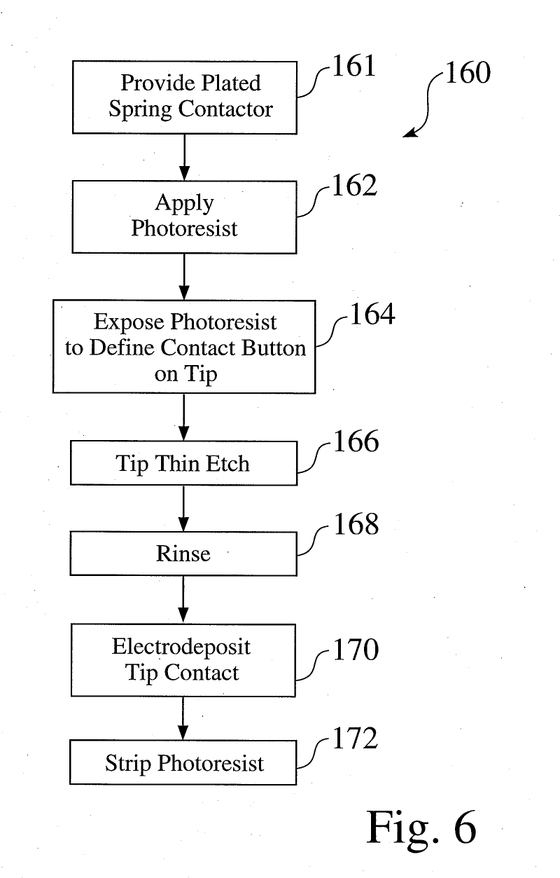

Thinned Tip Plated Spring Probes. FIG. 6 is a flowchart of a process 160 for forming a multiple plated spring 120 having a tip-thinned and plated tip area 128. FIG. 7 is a detailed partial cutaway view of a tip-thinned and plated tip spring 180 having a tip-thinned and plated tip area 128. FIG. 8 is a partial top view 200 of a tip-thinned and plated tip spring 180, such as comprising multiple plated spring 120 having a tip-thinned and plated tip area 128.

As seen in FIG. 6, an exemplary process 140 for forming a plated tip-thinned spring 180 (FIG. 7) typically comprises the step of providing 161 a plated spring contactor 120, such as seen above in FIG. 4 and FIG. 5. The plated spring contactor 120 typically comprises an elastic spring member 122, such as comprising one or more layers 88a-88n of metal, e.g. molybdenum chromium (MoCr), i.e. molychome, having different initial layers of stress before release from the substrate they are formed upon, such as directly or indirectly upon a substrate 30, e.g. comprising ceramic.

The plated spring contactor 120 also typically comprises subsequent plating layers formed on the elastic spring member 122, such as comprising a first structural layer 130, e.g. nickel (Ni), an adhesive layer 182, e.g. gold, a second structural layer, e.g. nickel (Ni), and an optional outer layer 184, e.g. such as nickel cobalt (NiCo).

Upon the spring structure 120, photoresist 462 (FIG. 26) is applied 162, and is then exposed 164 to define a contact button region 186 on the tip 128 of the structure 120, such as from the interface area 188 to the tip 128. The defined tip region 186 is then thin etched 166 and rinsed 168. A desired tip contact material, such as comprising palladium cobalt (PdCo), is then electro deposited on the exposed tip region 128 to form a contact button 187, and the photoresist 462 is then stripped 172 from the surrounding area.

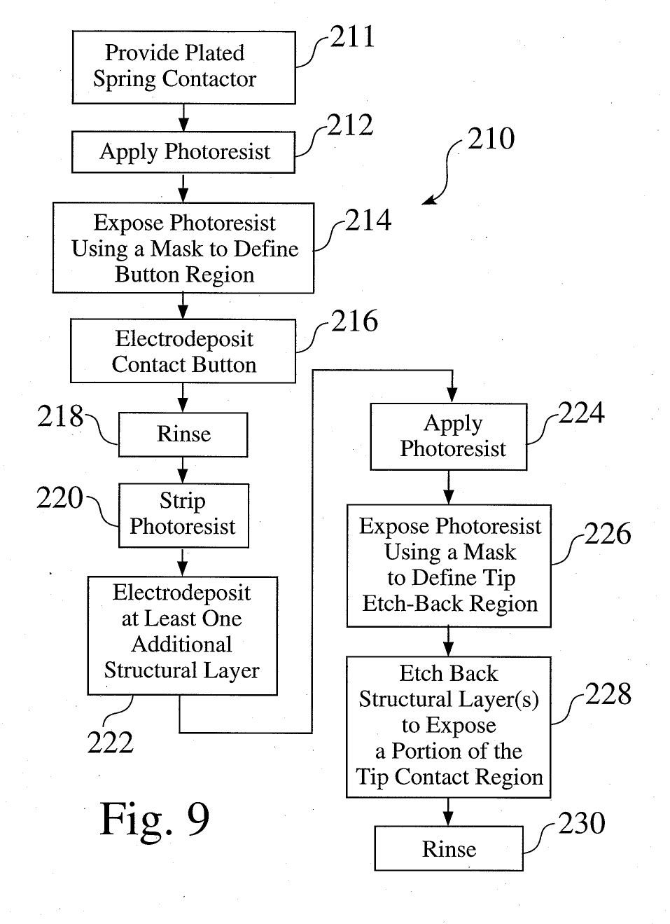

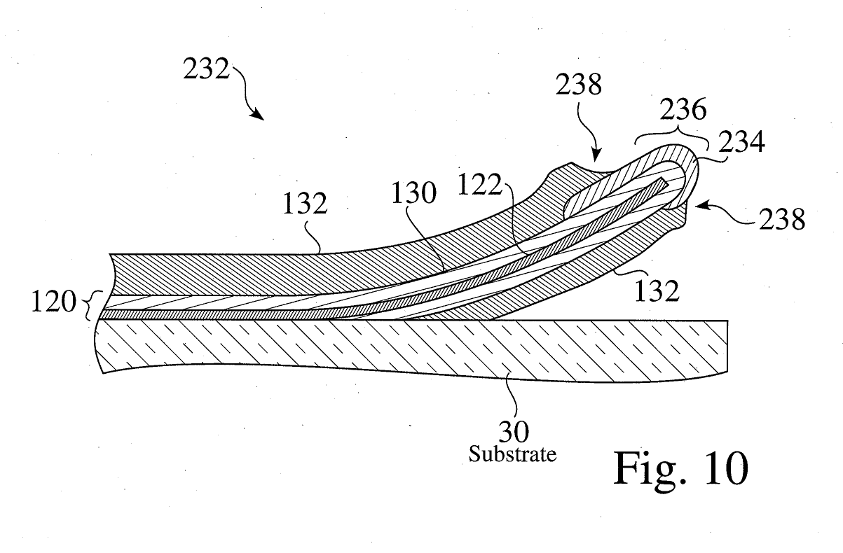

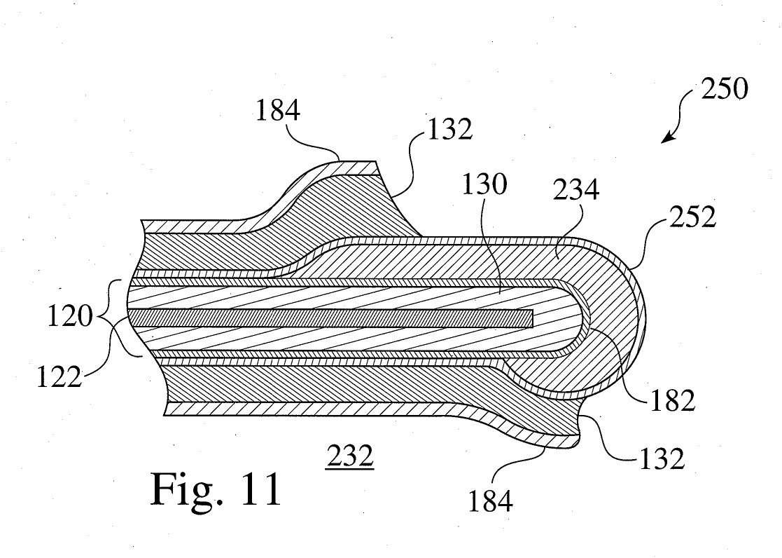

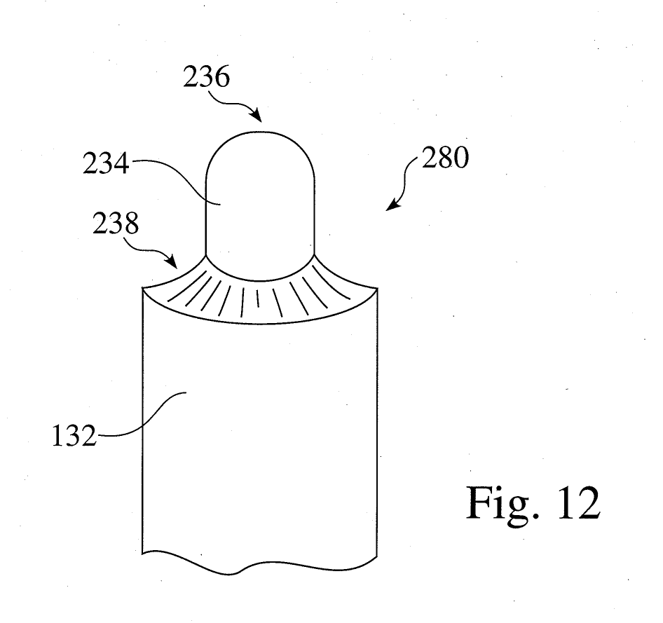

Double Button Spring Probes. FIG. 9 is a flowchart of a process 210 for forming a multiple plated spring having a double button structure 232 (FIG. 10). FIG. 10 is a partial cutaway view of a multiple plated spring having a double button tip structure 232. FIG. 11 is a detailed partial cutaway view 250 of a multiple plated spring having a double button tip structure 232. FIG. 12 is a partial top view 280 of a multiple plated spring having a double button tip structure 232.

As seen in FIG. 10, an exemplary process 210 for forming a double button structure 232 typically comprises the step of providing 211 a plated spring contactor 120, such as seen above in FIG. 4 and FIG. 5. As discussed above, a plated spring contactor 120 typically comprises an elastic spring member 122, such as comprising one or more layers 88a-88n of metal, e.g. molybdenum chromium (MoCr), i.e. molychome, having different initial layers of stress before release from the substrate they are formed upon, such as directly or indirectly upon a substrate 30, e.g. comprising ceramic.

The initial exemplary plated spring structure 120 seen in FIG. 10 typically comprises at least one initial plating layer, such as a first structural layer 130, e.g. comprising nickel (Ni). As seen in FIG. 11, the initial plated spring structure 120 may also preferably comprise at least one additional metal layer 182, such as an adhesion layer, e.g. gold (Au), over the first structural layer 130.

Upon the spring structure 120, photoresist 462 (FIG. 26), is applied 212, and is then exposed 214 to define a contact button region 236 on the tip 128 of the structure 120, such as extending from below an interface area 238 to the tip 128. A contact button metal 234 is then electrodeposited 216 on defined tip region 236. In some embodiments, the contact button metal 234 comprises palladium cobalt, such as 85% Pd/15% Co percent by weight. The assembly is then rinsed 218 and the photoresist 462 is stripped 200.

At least one further structural layer 132, e.g. nickel (Ni) is then preferably electrodeposited on the assembly, followed by an application 224 of another layer of photoresist 462. This layer of photoresist 462 is then exposed 226, using a mask to define a tip etch-back region. The additional structural layer is then etched back to expose a selected portion of the tip contact region 236, and the photoresist 462 is then removed by rinsing 230.

As seen in FIG. 11, other metal layers may be controllably applied in preferred embodiments of the process 210 and structure 232, such as:
the addition of a plating layer 252, e.g. gold (Au) over both the button 234 and extending down the spring over the adhesion layer 182; and/or
the addition of an outer layer 184, e.g. Ni or NiCo, that extends over the second structural layer 132.

FIG. 12 shows an end view 280 of the completed tip structure 236 in which tip portion 234 extends from core portion 132 with intervening transition region 238.

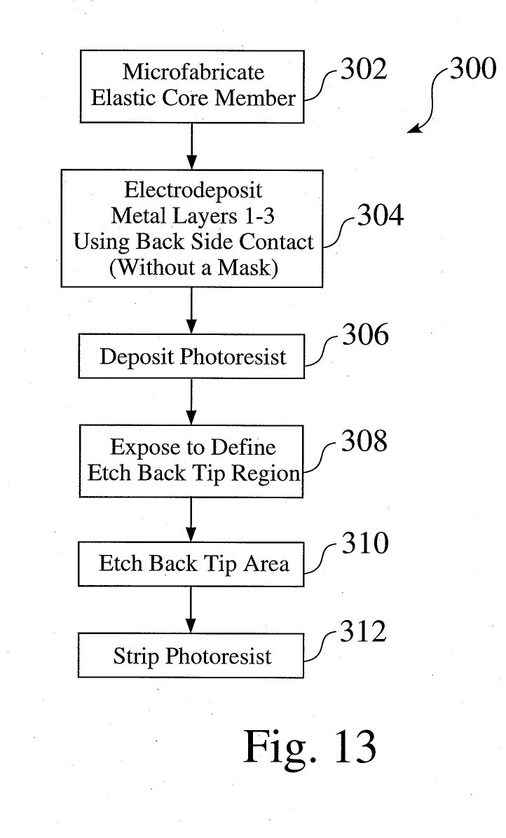

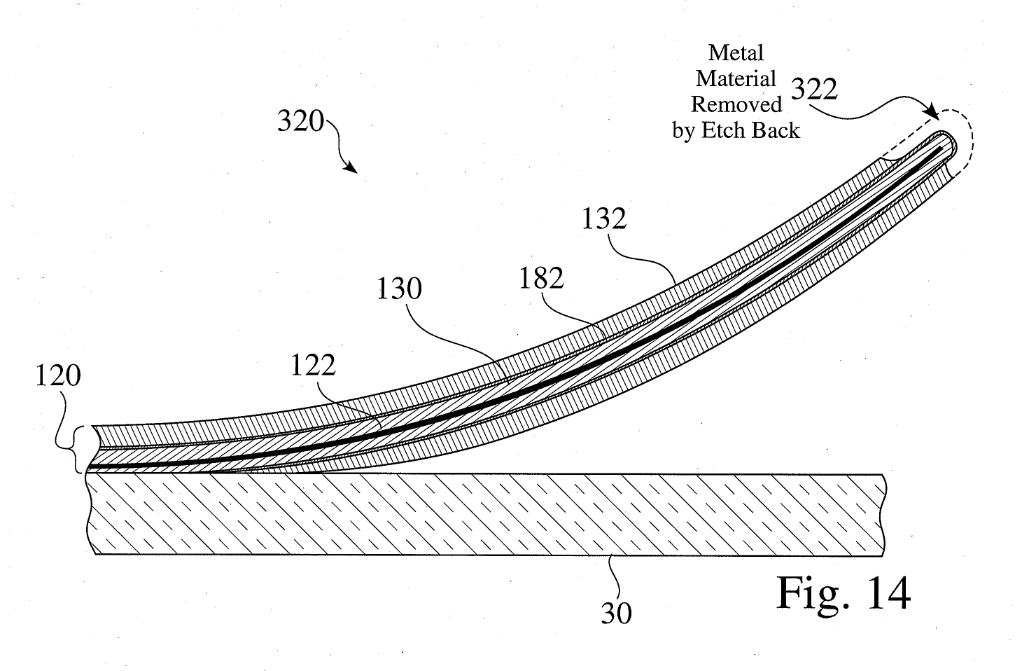

Etch Back Spring. Probes. FIG. 13 is a flowchart of a process 300 for forming an etch-back tip micro-fabricated spring probe 320. FIG. 14 is a partial cutaway view of a micro-fabricated spring probe 320 having an etch-back tip structure.

As seen in FIG. 13, an exemplary process 300 for forming an etch-back tip micro-fabricated spring probe 320 typically comprises the step of microfabricating 302 an elastic spring member 122, such as comprising one or more layers 88a-88n of metal, e.g. molybdenum chromium (MoCr), i.e. molychrome, having different initial layers of stress before release from the substrate they are formed upon, such as directly or indirectly upon a substrate 30, e.g. comprising ceramic.

One or more additional layers are then electrodeposited 304 on the elastic core member(s) 122), such as without a mask on the elastic core member(s) 122, and typically using a backside contact, e.g. 66,68 as an electrode for the process 304. In the exemplary contactor embodiment 320 seen in FIG. 14, the layers comprise a first structural layer 130, e.g. Ni, NiCo, a metal layer 182, e.g. PdCo, and a further structural metal layer 132, e.g. Ni, NiCo. The tip metal layer 182 seen in FIG. 14 is eventually exposed at the tip 128 of the structure 320, and may additionally provide adhesion layers, e.g. Au, between the structural layers 130,132.

A layer of photoresist 462 is then deposited 306 over the assembly, and is then selectably exposed 308 to define an etch-back tip region 322. The defined tip region 322 is then etched-back 310 to expose the plating layer 182 on the spring tip 128, and the photoresist 462 is then stripped 312.

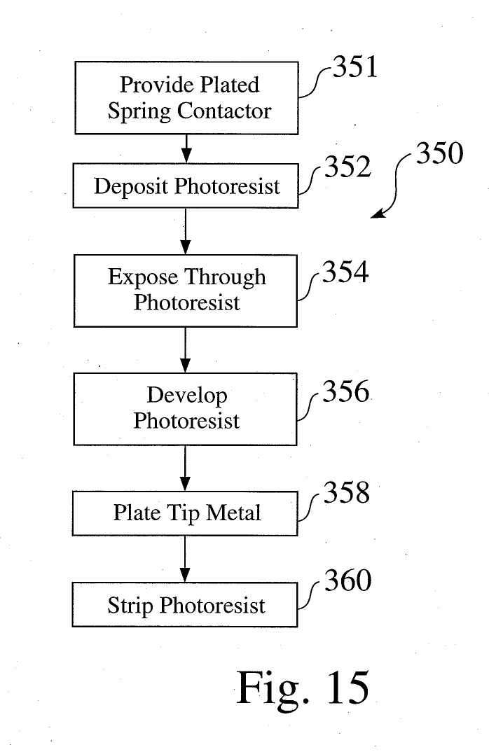

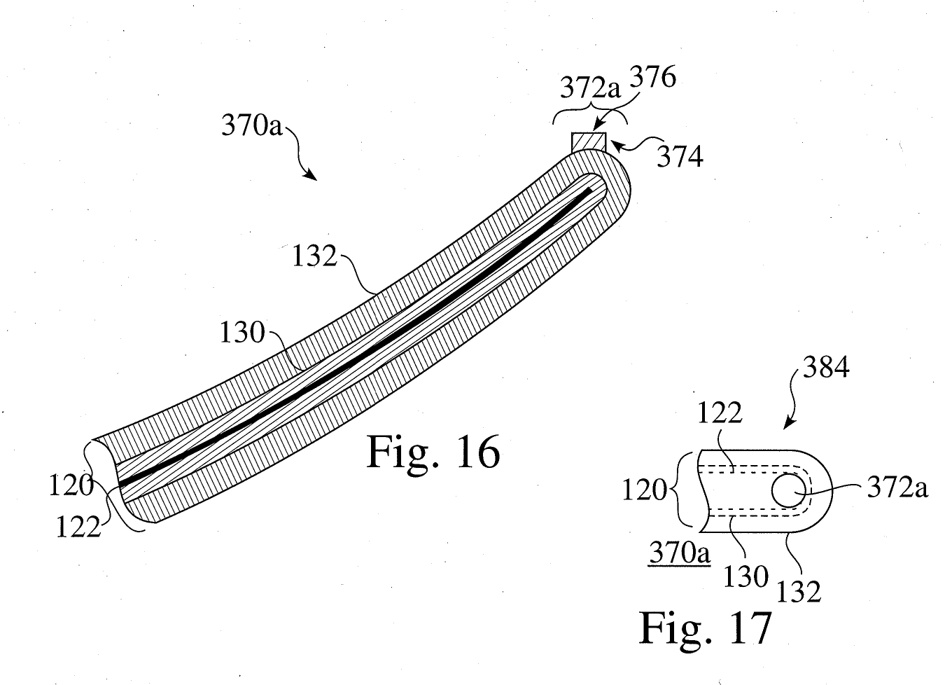

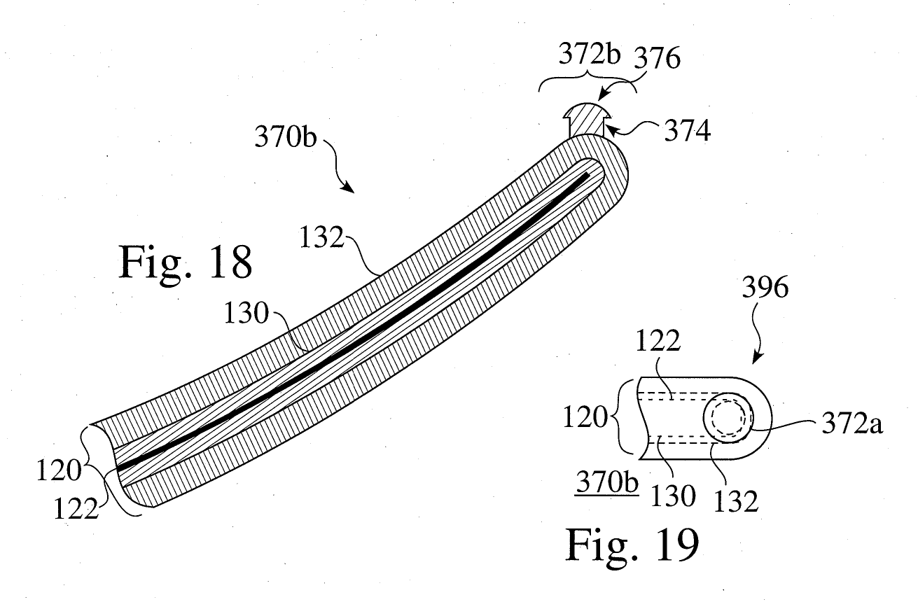

Tip Button Spring Probes. FIG. 15 is a flowchart of a process 350 for forming a spring having a formed tip button. FIG. 16 is a partial cross sectional view of a spring 370a having a formed flat contour tip button 372a. FIG. 17 is a partial top view 384 of a spring 370a having a formed flat contour tip button 372a. FIG. 18 is a partial cross sectional view of a spring 370b having a formed mushroom contour tip button 372b. FIG. 19 is a partial top view 396 of a spring 370b having a formed mushroom contour tip button 372b.

As seen in FIG. 15, an exemplary process 350 for forming an additive button structure 372, e.g. 372a,372b, typically comprises the step of providing 351 one or more plated spring contactors 120, such as seen in FIG. 4 and FIG. 5. As discussed above, a plated spring contactors 120 typically comprise an elastic spring members 122, such as comprising one or more layers 88a-88n of metal, e.g. molybdenum chromium (MoCr), i.e. molychome, having different initial layers of stress before release from the substrate they are formed upon, such as directly or indirectly upon a substrate 30, e.g. comprising ceramic.

The initial exemplary plated spring structures 120 seen in FIGS. 16-19 typically comprise at least one initial plating layer, such as a first structural layer 130, e.g. comprising nickel (Ni), NiCo, etc. The initial plated spring structures 120 may also preferably comprise at least one additional metal layer 182, such as an adhesion layer, e.g. gold (Au), over the first structural layer 130, and one or more additional structural layers 132.

Upon the spring structure 120, photoresist 462 is deposited 352, and is then exposed 354 to define button region 236 on the tip 128 of the structure 120. The photoresist 462 is then developed 356, and the desired tip metal 372 is then plated. When the desired contour 372 is complete, the photoresist 462 is stripped

As seen in FIG. 16 and FIG. 18, a wide variety of contours 372 may be provided for the additive tip buttons. For example, the spring 370a seen in FIG. 16 and FIG. 17 comprises a formed flat contour tip button 372a. As well, the spring 370b seen in FIG. 18 and FIG. 18 comprises a formed mushroom contour tip button 372b.

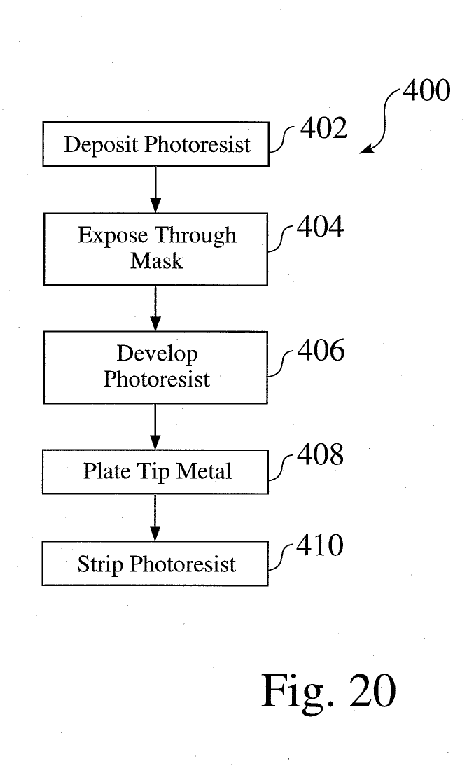

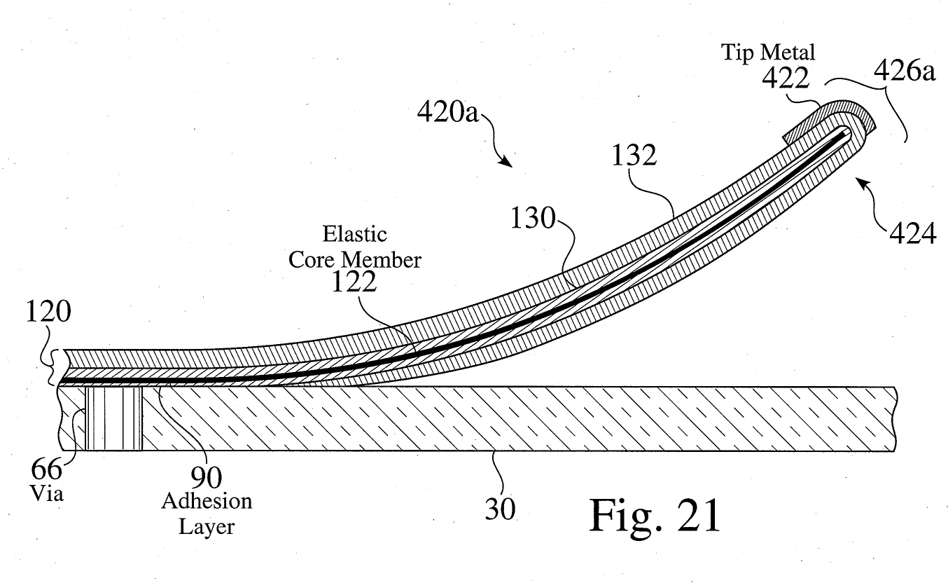

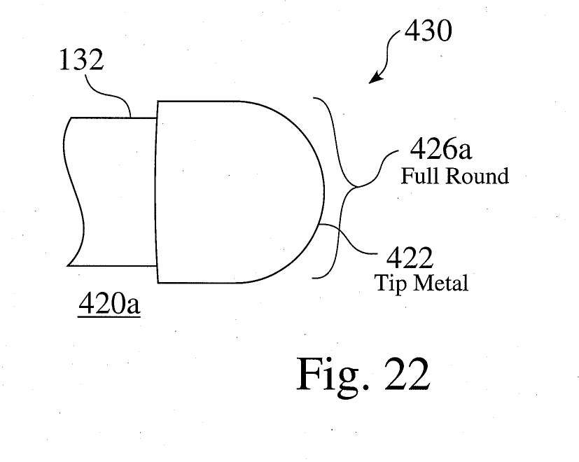

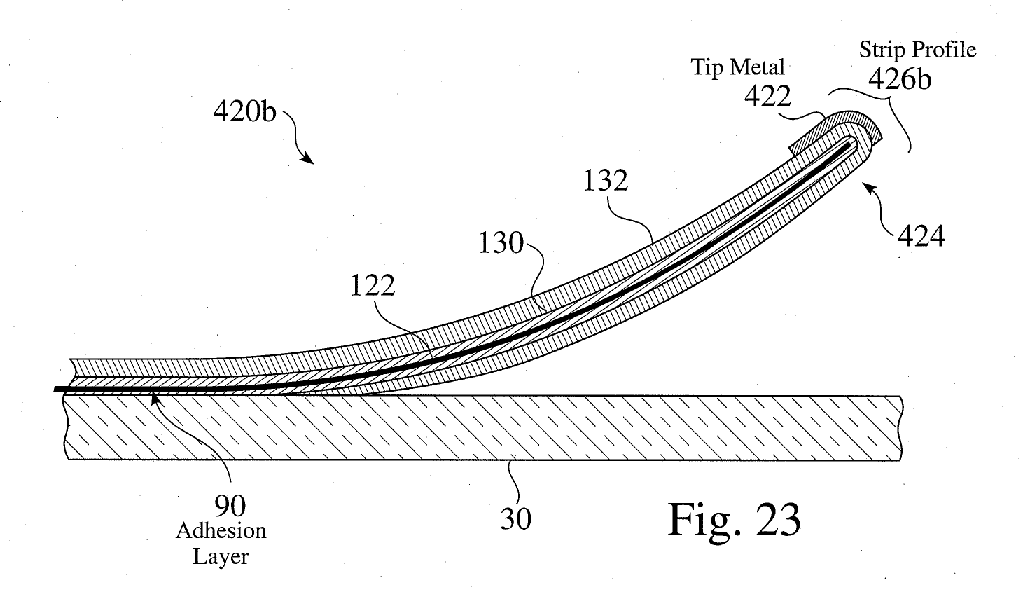

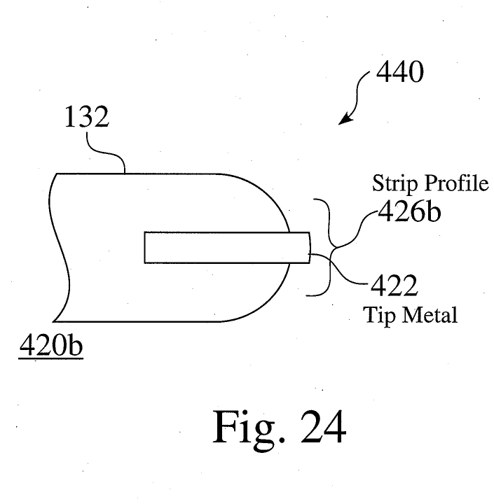

Additional Additive Tip Spring Probes. FIG. 20 is a flowchart of a process 400 for forming a spring 420, e.g. 420a,420b, having an additive tip metal region 426, e.g. 426a,426b. FIG. 21 is a partial cross sectional view of an exemplary spring 420a having a full round tip metal region 426a. FIG. 22 is a partial top view 430 of a spring 500a having a full round tip metal region 426a. FIG. 23 is a partial cross sectional view of a spring 420b having a central strip tip metal region 426b. FIG. 24 is a partial top view 440 of a spring 420b having a central strip tip metal region 426b.

As seen in FIG. 20, an exemplary process 400 for forming a spring 426 having a tip metal region 426, e.g. 426a,426b, typically comprises depositing 402 a layer of photoresist 462 on a spring structure 120. The structure 120 is then selectably exposed 404 through the photoresist mask 472 (FIG. 27). The photoresist 462 is then developed 406, and the tip 128 of the structure 120 is then plated 408 with the desired tip metal. The photoresist 462 is then stripped 410, to reveal the completed additive tip 506.

For an exemplary spring 420a having a full round tip metal region 426a, as seen in FIG. 21 and FIG. 22, photoresist 462 is deposited 402 and exposed 404 through mask 472. A full round tip metal 422 is the plateably formed 408 through the opening in exposed photoresist 462 and subsequently, the photoresist 462 is stripped 410, leaving the full round tip structure 426a on the spring structure 120. Similarly, for an exemplary spring 420b having a strip profile tip metal region 426b, as seen in FIG. 23 and FIG. 24, the pattern in mask 472 and process steps 402 through 410 of process 400 are performed. One skilled in the art will understand that by changing the mask pattern 472 many different additive tips with a great variety of shapes and profiles can be fabricated.

The spring structures 120 may typically comprise an elastic core member 122, e.g. comprising one or more spring layers 88 having different initial levels of stress before release from the substrate 30. As well, one or more structural layers, e.g. 130, 132, may be developed on the spring structure, such as comprising the upper surface of the fixed region of the spring member 122 and surrounding the non-planar portions of the free end and tip of the spring 122. As well, further layers may be provided between the structural layers shown, such as but not limited to an adhesion layer 182 between the elastic core member 122 and a first structural layer 130, and/or an adhesion layer 184 between structural layers 130 and 132. Further plating or structural layers may also be applied to the structures shown.

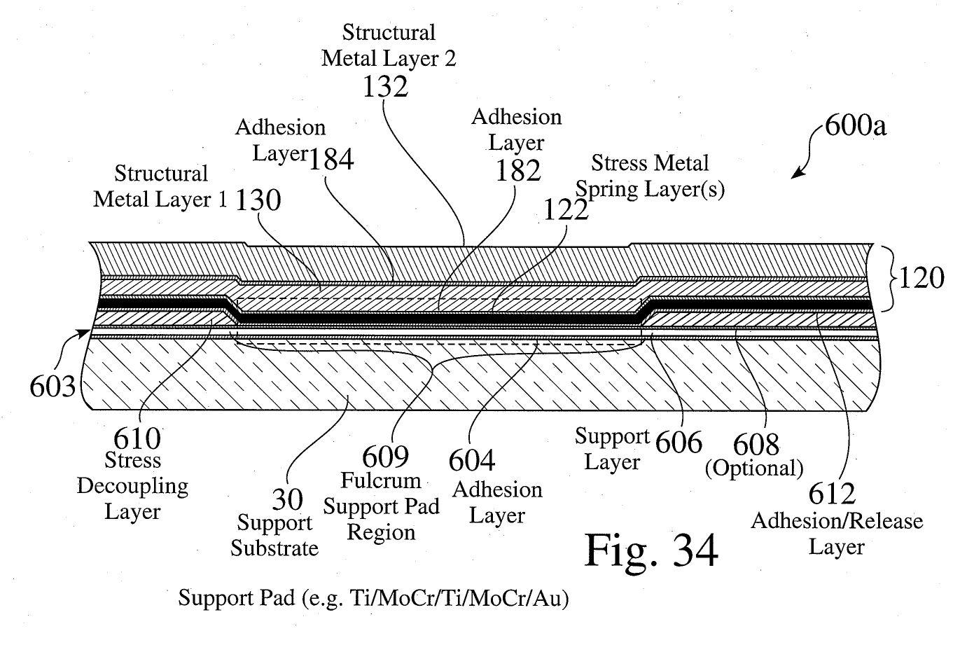

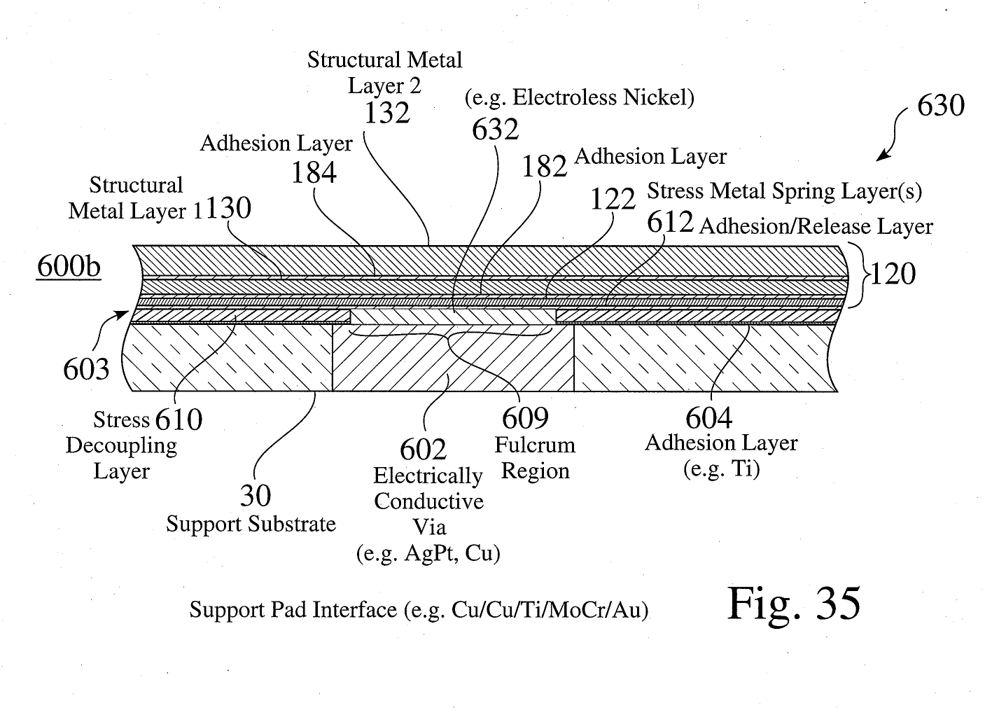

Exemplary Processing for Plated Spring Structures. FIG. 25 is a partial cutaway view 450 of an exemplary spring 454 extending from a substrate structure 452, and comprising one or more plating layers, e.g. 130,132 on an elastic member 122, to be used as a work piece in a spring enhancement process 160 (FIG. 6). While the substrate structure 452 may comprise a substrate 30, the substrate structure 452 may alternately comprise a wide variety of structures, such as including a stress decoupling structure 603 (FIG. 34, FIG. 35), e.g. having a stress decoupling layer 610. As noted above, the elastic spring member 122 may typically comprise one or more layers 88, e.g. 88a-88n (FIG. 3) having different inherent levels of stress before release from the substrate structure 452.

FIG. 26 is an exemplary view 460 showing the application 162 (FIG. 6) of a photoresist layer 462 on a plated spring 454 and substrate work piece. In some embodiments, an electrodeposited photoresist layer 462 having a thickness of about 6 to 7 μm is applied 162.

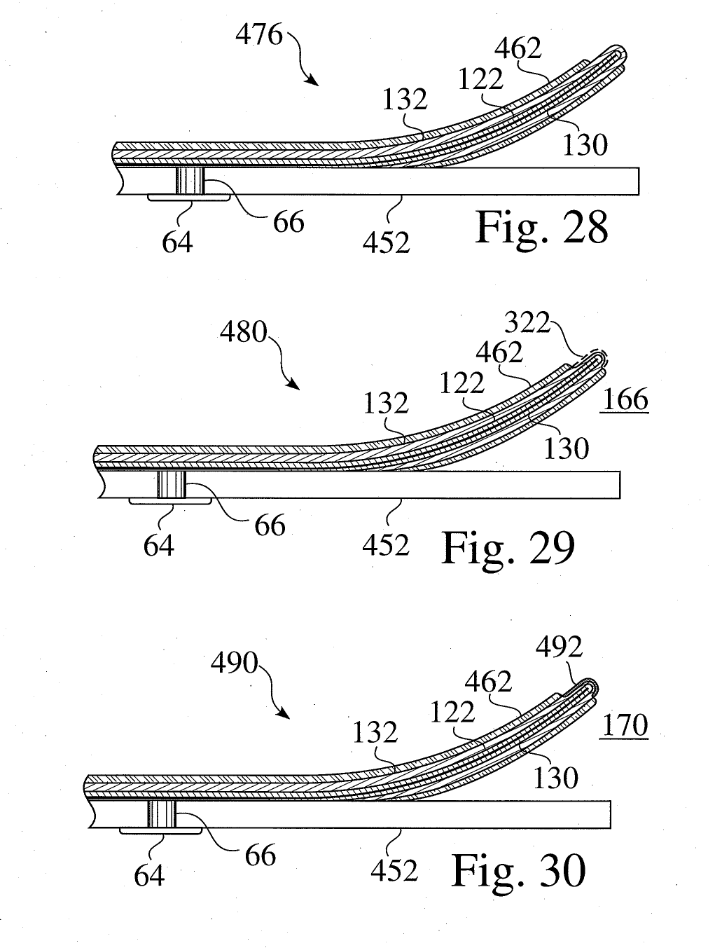

FIG. 27 is an exemplary view 470 showing controlled exposure 164 of a portion of photoresist layer 462 on a plated spring and substrate work piece. In some process embodiments 160, a mask 472, having holes 474 defined therethrough, is used to apply 162 the photoresist 462. FIG. 28 shows the controlled development 476 of a portion of photoresist layer 462 on a plated spring and substrate work piece, wherein a portion of the photoresist 462 is controllably removed, such as to provide access to the tip 128 of the plated spring 120 for subsequent processing.

FIG. 29 is an exemplary view 480 showing a partial etch back 166 of a portion of at least one plating layer on a plated spring 120 and substrate work piece. In the exemplary structure seen in FIG. 29, a portion of the metal plating layer 130, e.g. NiCo, is etched back about 9-10 μm, such as to define an etch back region 322 at the tip 128 of the elastic spring member 120.

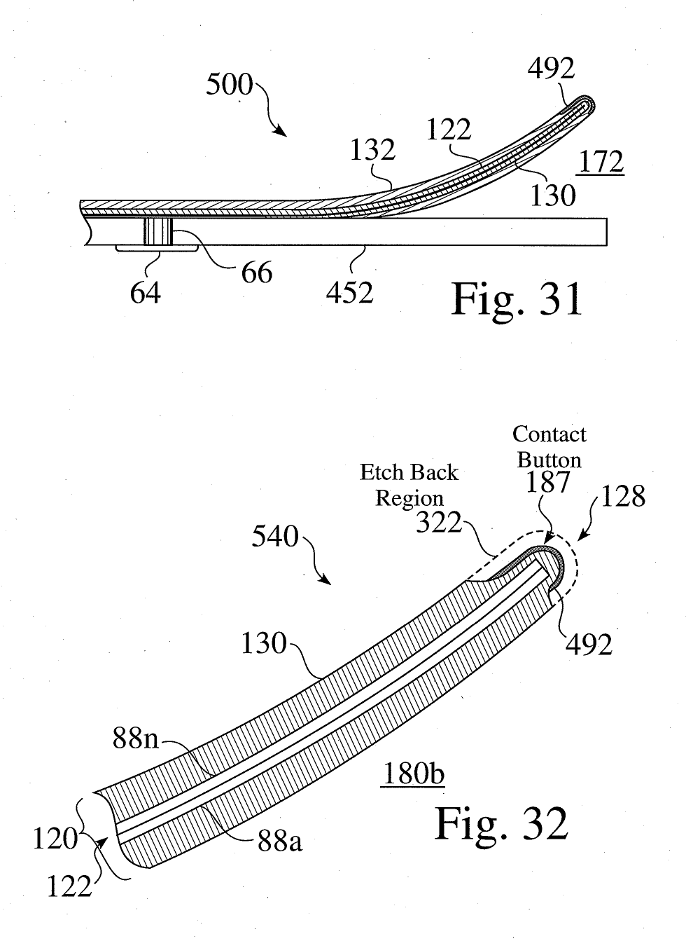

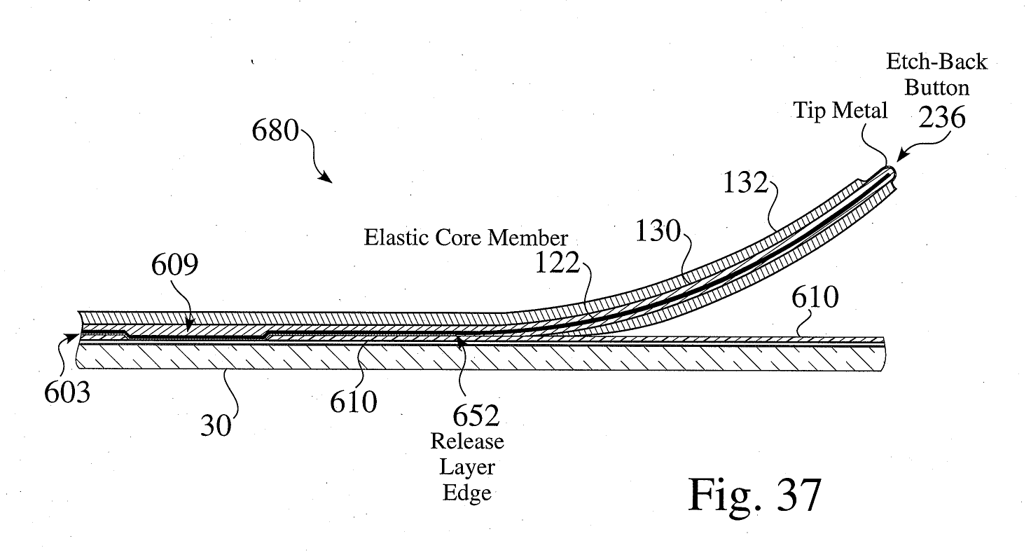

FIG. 30 is an exemplary view 490 showing controllable plating 170 of an etch back region 322 on a plated spring and substrate work piece, such as to provide a plated tip 492, e.g. comprising PdCo, such as to provide a durable, low resistance contact button 187 (FIG. 37) at the tip of the spring 120. In some embodiments, the plated tip 492 has a thickness of about 2 to 10 μm. FIG. 31 is an exemplary view 500 showing the stripping 172 of photoresist 462 from a plated etch back plated spring 120 and substrate work piece.

As seen in FIG. 31, the resultant plated spring structure comprises at least one elastic member 122 extending from a surface of a substrate structure 452, e.g. comprising a substrate 30, and in some embodiments, further comprising a stress decoupling structure 603 (FIG. 34, FIG. 35), e.g. having a stress decoupling layer 610. The one elastic members 122 also typically comprise one or more continuous plating layers, e.g. 130,132, which may preferably include a plated top 492, such as within an etch back region 322 formed through one or more of the plating layers 130,132.

FIG. 32 is a structural view 540 of an alternate embodiment of a spring structure 180b comprising an etched back and plated tip region 128, wherein the provided spring structure 120 comprises a single primary plating layer 130, which is then processed 160 as described in FIG. 6. Spring structures 180b can be fabricated on substrates that may or may not comprise a stress decoupling layer 610.

Planarization Structures and Processing. FIG. 33 is a schematic view of an exemplary planarization fixture 554 for planarization of spring structures, such as for various embodiments of plated spring structures 120 and/or decoupled spring structures 600. For example, the controlled processing of spring structures can improve co-planarity of the plated metal probe tips 120, e.g. stress metal springs 120, of a probe chip assembly 18. The probe chip substrate 30 is held flat against the flat surface of a reference chuck 562, e.g. such as a vacuum or electrostatic chuck 562. A precision shim 566 is placed on the surface at the periphery of the probe chip substrate 30, and rests upon a flat substrate 558, e.g. glass 558, which is located on a lower flat reference surface 560. A flat reference surface 564 is placed on top of the upper reference chuck 562 and the shim 566, thus compressing the spring probes 120 such that the probe tips 128 are located at exactly the same height relative to the back side of the probe chip substrate 30. In one planarization process embodiment, the assembly, e.g. 120,600, is then heated in the oven 556 to between about 175 degrees Centigrade to about 225 degrees Centigrade for a time period of between about 1 hour to about 3 hours, to allow the spring probes 120 to anneal and conform to the flat and planar reference surface 558,560. The system 554 is then slowly cooled, such as to optimally relieve stresses generated by the difference in the coefficients of thermal expansion between the ceramic substrate 572 and the probe chip plating layers, e.g. 130, 132.

In an alternative embodiment, the probe tips 128 are made parallel to the front surface 144a of the probe chip substrate 30, by replacing glass substrate 558 with a chuck 558 having a flat surface and one or more recesses, for the spring probes 120, wherein recesses are fabricated with a precise depth. The front surface 144a of the substrate 30 is then held flat against the chuck flat surface 558, and the spring probes 120 are compressed against the lower surface of the recesses. This method of planarization minimizes the effect of variation in the thickness of the substrate 30 and compression of the spring probes 120. The method also helps to maintain coplanarity of the probe tips 128, after subsequent processing steps. For example, variations in substrate thickness 30 can decrease probe tip planarity after solder bonding, if the probe chip 68 is held flat against its front surface 144a during bonding if it was held flat against its back surface 144b during probe tip planarization.

Decoupled Spring Contactors. Microfabricated spring contacts formed directly on support substrates 30, or having a single adhesion/release layer 90 between the elastic spring members 122 and a support substrate, are relatively simple to form and process, and have been demonstrated over time.

However, for some contactor embodiments, such microfabricated spring contacts have demonstrated disadvantages for some applications. For example, springs formed directly on support substrates 30, or having a single adhesion/release layer 90 between the elastic spring members 122 and a support substrate, may have a limited adhesion margin, and may be weakened by process temperatures. As well, as key process parameters are coupled, the effective fulcrum point for such microfabricated springs may change with process variations. In addition, these types of behaviors for such springs may be hard to model.

Some factors which may limit the use of microfabricated spring contacts formed directly on support substrates 30, or having a single adhesion/release layer 90 between the elastic spring members 122 and a support substrate, may include any of:
Adhesion margin limitations;
Ceramic-metal thermal coefficient of expansion (TCE) mismatch;
Interface stress from structural sources;
Process variation in fulcrum locations; and/or
Contact requirements for contact pads having passivation layers, e.g. about 3 to about 10 micron thick passivation layers.

Factors which may limit adhesion margin for microfabricated spring contacts formed directly on support substrates 30, or having a single adhesion/release layer 90 between the elastic spring members 122 and a support substrate, may comprise any of:
Bond strength between support substrates and adhesion release layers, e.g. Ti-ceramic bonds;
Anchor characteristics; and/or
Elevated temperature process steps (temperatures and times).

As well, a TCE mismatch between typical support substrates, e.g. comprising ceramic, to neighboring metal layers, e.g. an adhesion layer, can be significant, such as for temperatures associated with any of planarization, annealing, testing, and/or operation. Such a TCE mismatch can create interface stresses, which may lead to delamination, such as during thermal process steps, e.g. heat treatment and anneal.

Furthermore, the use of some metals for springs, such as NiCo, NiW, NiFe, can produce springs capable of higher force then nickel for the same cross sectional area due to higher Young's modulus, ultimate tensile strength, and fracture toughness. Springs having finer pitch can be fabricated using these materials and for the same probing force, the interfacial stresses tend to increase.

However, the use of such metals for microfabricated spring contacts formed directly on support substrates 30, or having a single adhesion/release layer 90 between the elastic spring members 122 and a support substrate, can be problematic, since the higher temperatures and/or longer times are often required for elevated temperature processing steps of such metals, e.g. such as for heat treatment and/or annealing processes can lead to delamination.

Structural sources of interface stress in prior microfabricated spring contacts formed directly on support substrates 30 may comprise any of finger plating overhang on edges (a vertical components of stress), finger plating width (a horizontal component of stress), and/or finger plating length (a horizontal component of stress).

FIG. 34 is a partial cross sectional view of a first exemplary embodiment of a stress decoupling structure 600a for a formed spring, such as but not limited a plated spring 120 (FIG. 4, FIG. 5). FIG. 35 is a partial cross sectional view 630 of a second exemplary embodiment 600b of a stress decoupling structure 600b for a formed spring, e.g. a plated spring 120. The stress decoupling layer 603 shown in both FIG. 34 and FIG. 35 may preferably serve multiple purposes including, but not limited to, providing relief for both vertical and horizontal stresses associated with TCE mismatches and mechanical deflection.

As seen in FIG. 34 and FIG. 35, one or more fulcrum structures 609 are formed upon a support substrate 30 in relation to springs, when a stress decoupling structure 603 is established between a surface 142a of the substrate and the spring structure 120.

In the exemplary structure 600a seen in FIG. 34, a patterned electrically conductive support layer 606, such as comprising MoCr or Ni, is established over the support substrate 30. An adhesion layer 604 is preferably first formed on the substrate 30, to promote adhesion between the substrate 30 and the support layer 604. An optional electrically conductive support adhesion layer 608, such as comprising titanium (Ti) may also preferably established over the support layer 606.

The support structure comprises a stress decoupling layer 610, which in current embodiments comprises an electrically insulative layer 610, e.g. polyimide (PI). that is typically formed over the adhesion layer 604, and is then typically patterned and selectively removed, to define fulcrum regions 609, wherein selective portions of the fixed regions 124 of spring structures, e.g. 120, are formably secured through the support structure 603.

For example, the exemplary spring structure seen in FIG. 34 comprises an adhesion/release layer 612, such as comprising titanium (Ti) or gold (Au), established on the decoupling layer 610, and extending through the fulcrum regions 609 of the decoupling layer 610 to form mechanical and electrical connections to the support structure 603, e.g. such as to the adhesion layer 608. The elastic spring elements 122, such as comprising one or more layers 88 of MoCr, e.g. two or more layers 88a-88n, are then formed on the adhesion/release layer 612.

As described above, the spring elements 122 are then typically photolithography formed, etched, and released, such that portions of the spring elements 122 are released and extend away from the plane of the substrate 30. Similarly, the spring elements 122 may then be controllably processed, such as through one or more plating and/or etching processes, to form desired spring and/or tip structures.

For example, as seen in FIG. 34, an adhesion layer 182, such as comprising gold (Au) may be applied to the elastic members 122, to promote adhesion to a subsequent structural metal layer 130, such as comprising nickel (Ni). Similarly, another adhesion layer 184, such as comprising gold (Au), may be applied to the first structural metal layer 130, to promote adhesion to a second structural metal layer 132, such as comprising nickel cobalt (NiCo).

In the exemplary structure 600b seen in FIG. 35, a stress decoupling layer 610, such as comprising polyimide, is either formed directly on the substrate 30, or over the intermediate adhesion layer 604, such as comprising titanium (Ti). The application of an intermediate adhesion layer 604 may be preferred, such as to promote adhesion between the substrate 30 and a stress decoupling layer 610.

The stress decoupling layer 610 is then typically patterned and selectively removed, to define one or more fulcrum regions 609 wherein selective portions of the fixed regions 124 of spring structures, e.g. 120, are formably secured to lower conductive structures and/or pathways, such as but not limited to electrically conductive vias 66.

In the exemplary decoupled spring structure 600b seen in FIG. 35, a support pad layer 632 is established within the fulcrum regions 609, such as to fill at least a portion of the fulcrum regions. For example, the height of the support pad layer 632 seen in FIG. 35 26 fills the entire thickness of the decoupling layer 610. The width, length or diameter of the support pad regions 632 can be the same as, smaller or larger than the electrically conductive vias to which they are physically and electrically connected. In some exemplary embodiments 600b, support pad regions 632 may comprise any of copper (Cu), titanium (Ti), MoCr, gold (Au), or any combination thereof.

The exemplary spring structure seen in FIG. 35 comprises an adhesion/release layer 612, such as comprising titanium (Ti) or gold (Au) established on the decoupling layer 610, that extends through the fulcrum regions 609 of the decoupling layer 610 to form one or more mechanical and electrical connections to the support structure 603, e.g. such as to the adhesion layer 608. The elastic spring element 122, such as comprising one or more layers 88, e.g. two or more layers 88a-88n of MoCr, is then formed on the adhesion layer 182.

As described above, the spring elements 122 are then typically photolithography formed, etched, and released, such that portions of the spring elements 122 are released and extend away from the plane of the substrate 30. Similarly, the spring elements 122 may then be controllably processed, such as through one or more plating and/or etching processes, to form desired spring and/or tip structures.

For example, as seen in FIG. 35, an adhesion layer 182, such as comprising gold (Au) may be applied to the elastic members 122, to promote adhesion to a subsequent structural metal layer 130, such as comprising nickel (Ni). Similarly, another adhesion layer 184, such as comprising gold (Au), may be applied to the first structural metal layer 130, to promote adhesion to a second structural metal layer 132, such as comprising nickel cobalt (NiCo).

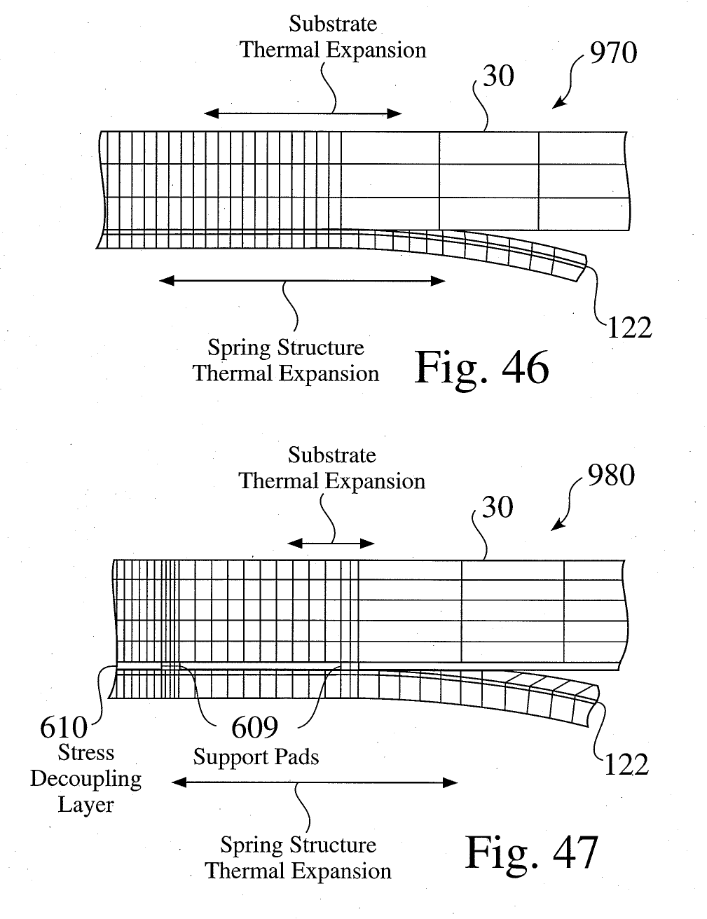

Decoupled spring structures 600, such as seen in FIG. 34 and FIG. 35, comprise an interface 603 comprising a stress decoupling layer 610 between elastic spring members 122, e.g. stress metal springs 122, and the support substrate 30, such as to decouple both vertical and horizontal stresses, as illustrated in FIGS. 46 and 47. The stress decoupling layer 610 preferably comprises a low modulus relative to the support substrate 30, which in many embodiments comprises a ceramic.

In some decoupled contactor embodiments 600, the stress decoupling layer 610 comprises a polymer, or any of polyimide, silicone, parylene, and/or any combination thereof. In some decoupled contactor embodiments 600, the thickness of the stress decoupling layer 610 is between about 0.1 micron and 1000 microns.

The stress decoupling layer interface 603 preferably provides good adhesion to both the support substrate 610 and the neighboring adhesion and/or release layer 612 of the elastic spring members 122. For example, the stress decoupling layer 610 preferably provides good adhesion to both the substrate 30, e.g. comprising a ceramic, and to the elastic spring members 122 through the adhesion/release layer 612. As well, the stress decoupling layer 610 preferably withstands required temperatures for spring contact heat treatment and annealing processes.

Decoupled spring structures 600 having a controllably formed stress decoupling layer 610 provide process independent means for control of fulcrum locations 609, i.e. defined electromechanical support pads 609, as the locations of the fulcrums 609 are controllably defined, and the regions of the spring structures, e.g. neighboring portions of the fixed spring region 124, surrounding the fulcrum regions 609 are not fixedly constrained.

A wide variety of spring structures, such as having fine pitch tip structures, can be established on decoupled base structures 600, e.g. 600a,600b, such as but not limited to spring structures that can be established directly upon a support substrate 30, such as additive button structures (FIG. 27), etch-back button structures (FIG. 28), etch-back continuous plating structures (FIG. 28), double button structures (FIGS. 9-12), and/or thinned tip structures (FIG. 6-8) can be similarly implemented on one or both surfaces of a substrate 30 having a decoupling layer 610.

Decoupled microcontactors 600, such as but not limited to the contactor assemblies seen in FIG. 34 and FIG. 35, may typically provide an interconnection apparatus for establishing electrical contact between two components. Such apparatus generally comprise one or more elastic core members 122 having an anchor portion 124 fixedly attached to a support substrate 30 by one or more support pads 609, wherein at least one of the respective support pads 609 extends through a stress decoupling layer 610, and wherein a free portion 126 of the elastic core members 122 extends away from the decoupling layer 610. In some embodiments, the free portion 126 is initially attached to the stress decoupling layer 610, and upon release, extends to a lift height 144 away from the stress decoupling layer 610, due inherent stress gradients in the elastic core members 122.

In some embodiments of decoupled microcontactors 600, the fulcrum locations of the core members are photolithographically defined. For example. the locations of the fulcrum locations of the core members may preferably be photolithographically defined to lie at a desired location between the respective edges of the release layer 612 and the tip 128 of the core members 122. The location of the fulcrum 609 between the edge of the release layer 612 and the tip 128 of the core members 122 may preferably be controlled by the thickness of one or more metal layers, e.g. 130, 182, 132,184, enveloping the core members, and by one or more post plating elevated temperature processing steps.

A wide variety of upper spring structures can be provided for decoupled microcontactors 600, such as but not limited to simple photolithographic springs that are formed en masse, as well as spring structures that are attached to a substrate assembly having decoupled structure 603. A wide variety of enhanced plated and/or etched spring structures can also be integrated with a support substrate 30 having a decoupling structure 603. Preferred spring structure embodiments, such as described above, can readily be implemented on a support substrate 30 having a decoupling structure 603, such as but not limited to additive button tip structures, an double button tip structures, etch-back continuous plating tip structures, and any combination thereof. As well, decoupled microcontactor structures may be implemented for one or both sides of interposer structures.

In an exemplary embodiment of a decoupled microcontactor 600 having an enhanced spring structure, a negative photoresist 462 is deposited on a decoupled microcontactor 600 having elastic spring members 122 and at least one structural metal layer, e.g. 130, to mask the tip area 128 on the structural metal layer 130 of the springs 120. A further structural metal layer 132 is then plated onto unmasked area of the first structural metal layer 130. The photoresist 462 is then removed from the tip area 128. As well, a further metal layer, e.g. 184 may preferably be plated over the entire spring fingers 120, such as by connecting a plating electrode from backside of the contactor 600, without using a mask.

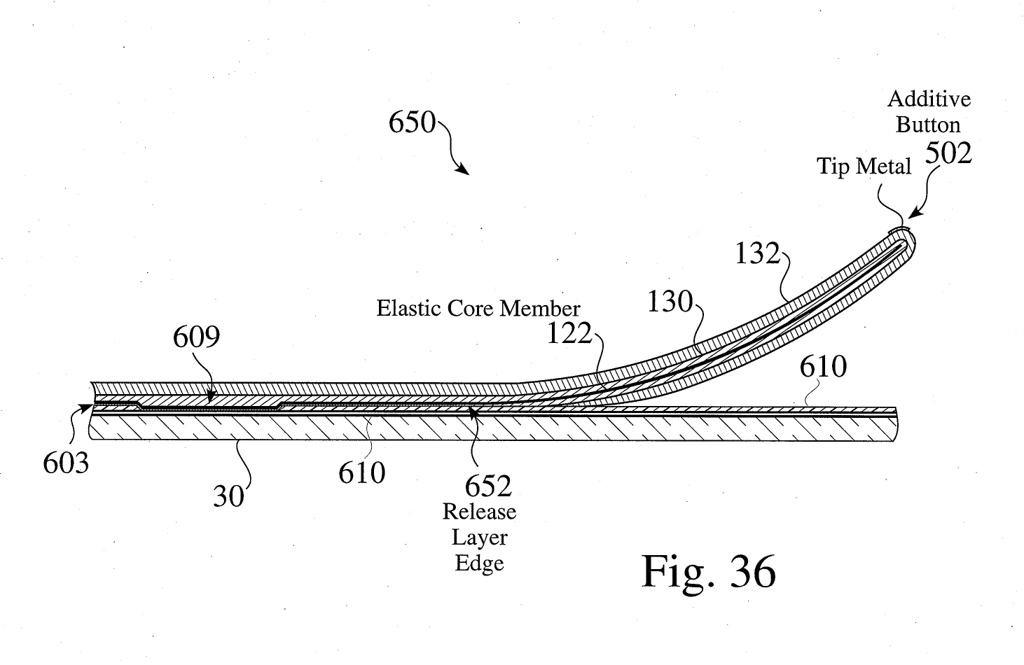

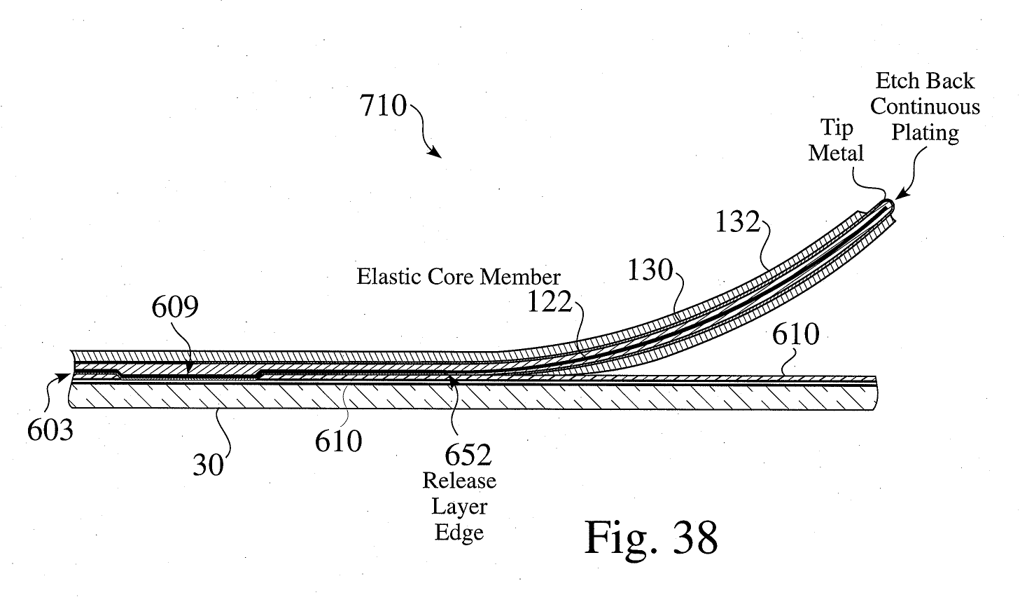

FIG. 36 is a partial cross sectional view of a spring structure 650 extending from a substrate 30 and having a decoupling surface structure 603, wherein the spring 120 has an additively formed button 502. FIG. 37 is a partial cross sectional view 680 of a spring extending from a substrate 30 having a decoupling surface structure 603, wherein the spring 120 has an etched-back contact structure 236. FIG. 38 is a partial cross sectional view 710 of a plated spring 120 extending from a substrate 30 having a decoupling surface structure 603, wherein the plated spring 120 has an etched-back continuous plating structure 236. The enhanced spring embodiments seen in FIG. 36, FIG. 37 and FIG. 38 can be fabricated using either negative or positive photo resist processes.

In some embodiments, the photoresist 462 is electrodeposited photoresist (EDPR), which inherently forms a relatively uniform, defect free conformal coating with constant thickness enveloping the surface of a 3-D spring contact structure. EDPR can be photolithographically patterned to allow etching or plating in areas defined by a mask.

EDPR can interact chemically with certain process chemicals, causing artifacts such as electroplating through the layer of EDPR. These chemical interactions can be minimized, such as by modifying the process, i.e. adjusting plating or etching solution pH, temperature, electrolyte concentrations, additive concentrations, etc.

In some embodiments of decoupled contactors 600, the photoresist 462 comprises conventional photoresist (CPR), which is applied by spray or spin processes. CPR processes are preferably modified to achieve uniform and defect free coatings in the region of the spring contact tips, i.e. by process modifications to remove bubbles from uncoated areas of the spring contacts and by reducing optical reflections, i.e. by adding an absorbing dye to the CPR. In some embodiments, the photoresist 462 is deposited from the vapor phase, to achieve a uniform and defect free coating in the region of the spring contact tips 128.

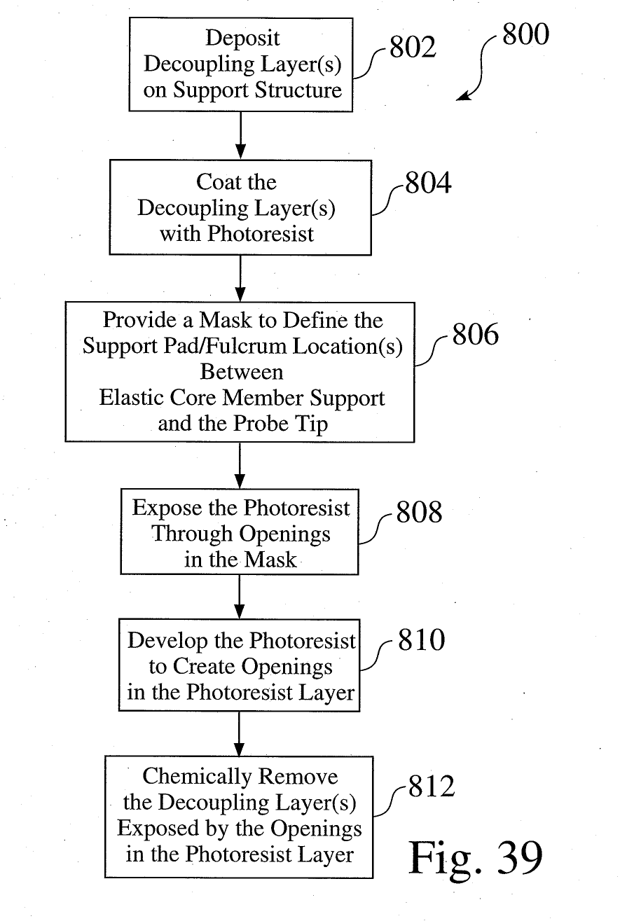

FIG. 39 is an exemplary flowchart for processing 800 of release layers associated with microcontactors 600 having decoupling structures 603. An adhesion/release layer 612 is typically deposited on the support structure 603, such as directly to the decoupling layer 610. The release layer 612 is then coated 804 with photoresist 462. A mask is then provided 806 to define the edges of the release layer 612, such as to a location between the elastic core member support and the probe tips 128. The photoresist 462 is then exposed 808, and then developed 810 to create openings in the photoresist layer 462. Exposed portions of the release layer 612 are then chemically removed 812.

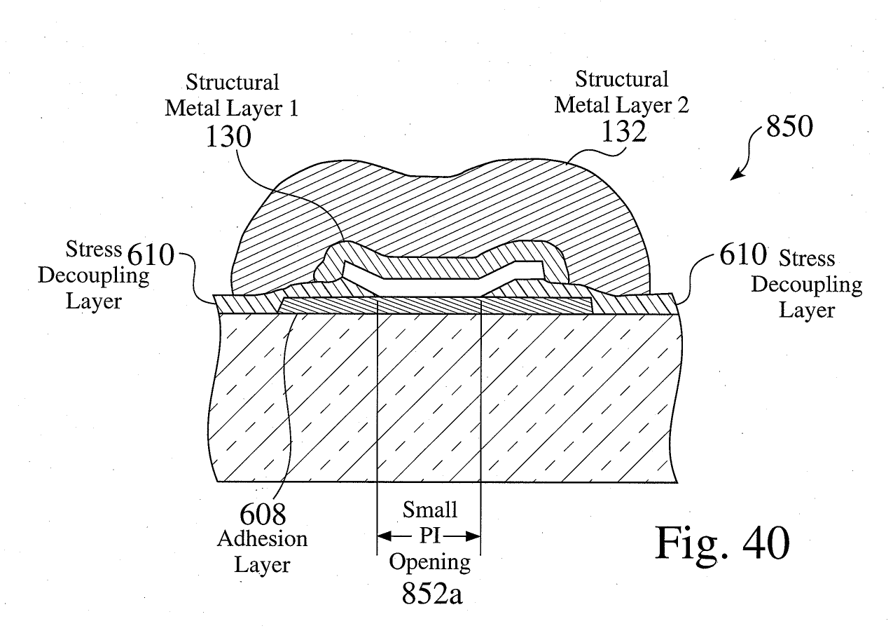

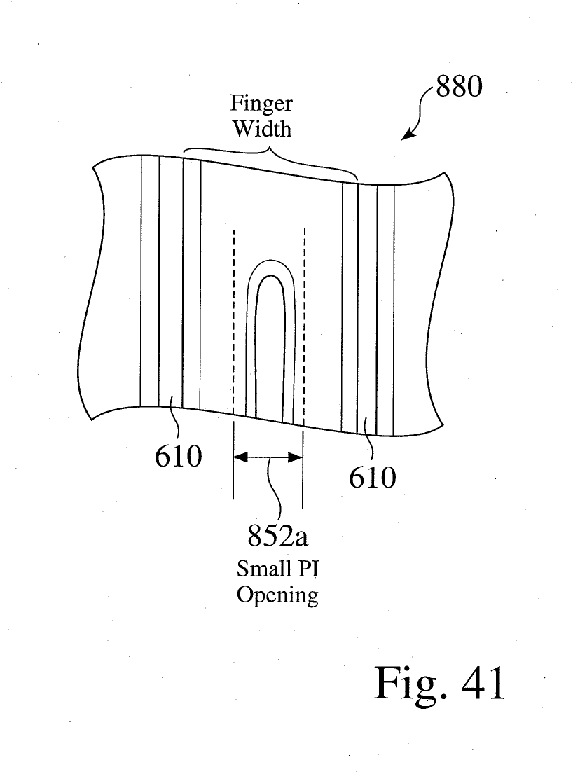

Supplementary Views of Decoupled Spring contactor Structures. FIG. 40 is a partial lateral cutaway view 850 of a spring formed on a substrate 30 having a decoupling surface structure 603, wherein the structure comprises a small PI opening 852a. FIG. 41 is a partial top view 880 of springs formed on a substrate 30 having a decoupling surface structure, wherein the structure comprises small fulcrum connection 609 and associated decoupling layer opening 852a in a surrounding decoupling layer 610. In some embodiments of springs 120 formed on a substrate 30 having a decoupling surface structure 603, small fulcrum connection areas 609 allow fabrication of finer pitch springs, while the fulcrum connection areas 609 are preferably large enough to resist delamination.

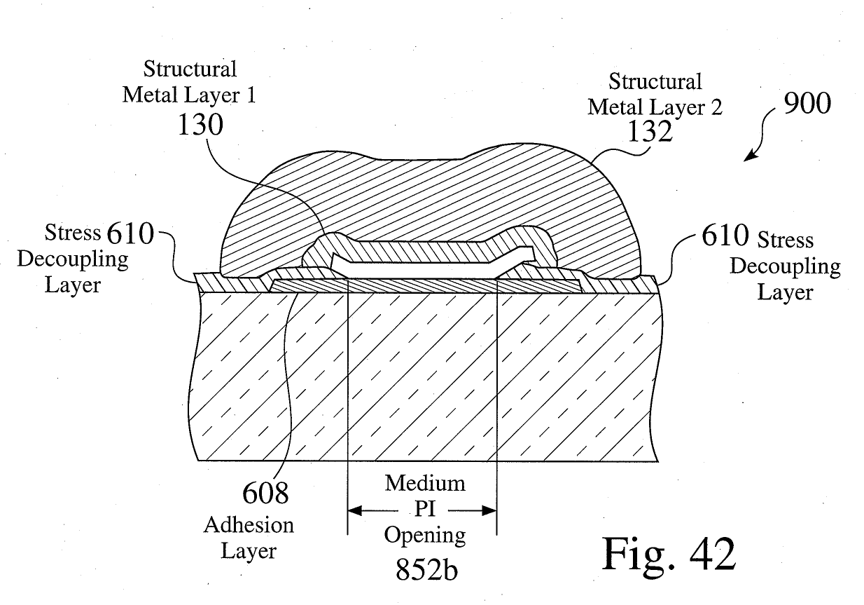

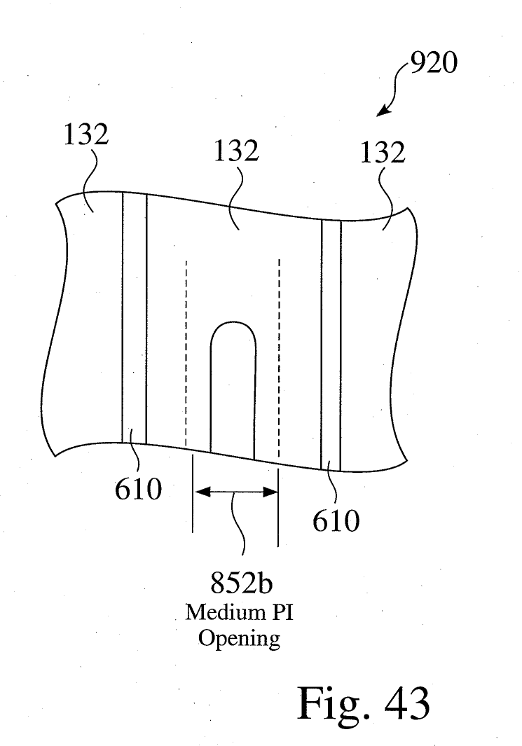

FIG. 42 is a partial lateral cutaway view 900 of a spring formed on a substrate 30 having a decoupling surface structure 603, wherein the structure 603 comprises a medium sized PI opening 852b. FIG. 43 is a partial top view 920 of springs formed on a substrate 30 having a decoupling surface structure 603, wherein the structure comprises medium sized fulcrum connections 609 and associated medium sized decoupling layer openings 852b in a surrounding decoupling layer 610. The exemplary medium sized fulcrum connection seen in FIG. 42 provides both resistance to both delamination and spring breakage.

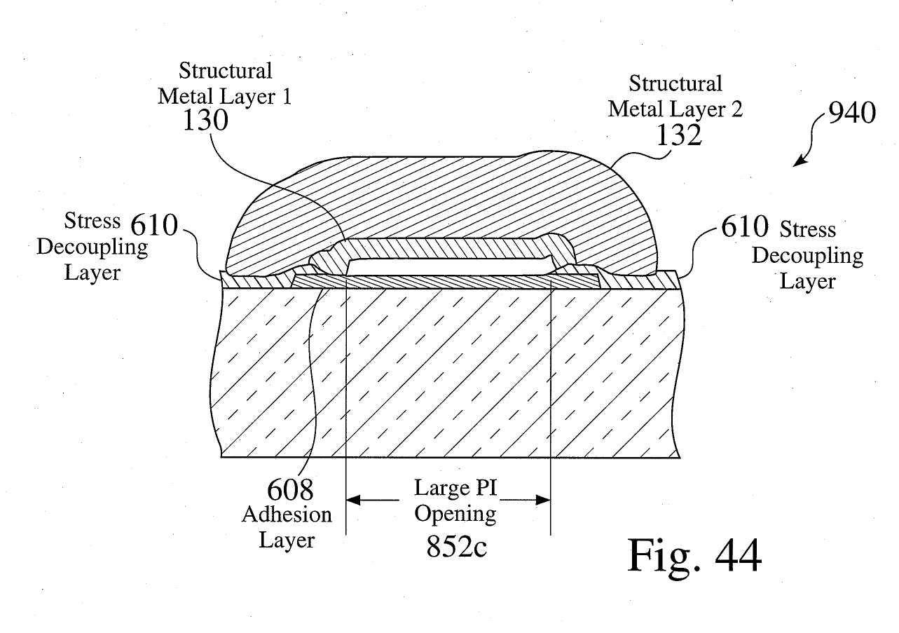

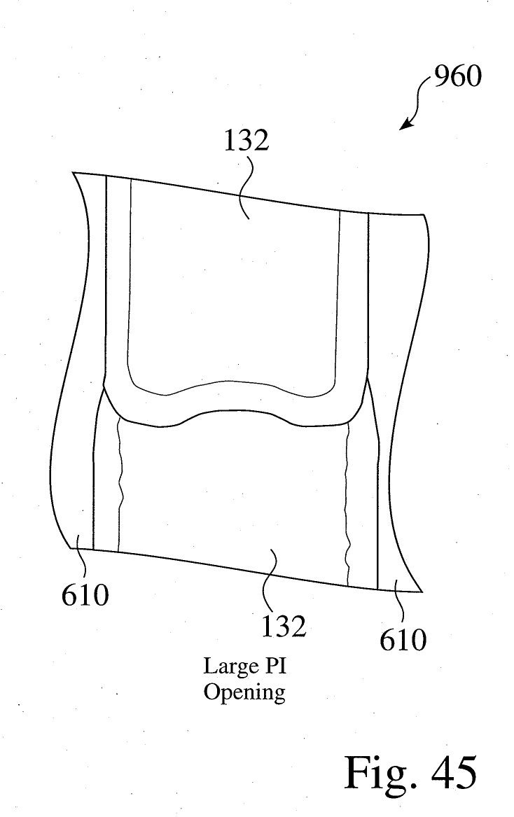

FIG. 44 is a partial lateral cutaway view 940 of a spring formed on a substrate 30 having a decoupling surface structure 603, wherein the structure comprises a large PI opening. FIG. 45 is a partial top view 960 of a spring formed on a substrate 30 having a decoupling surface structure, wherein the contact structure comprises large sized fulcrum connections 609 and associated large sized decoupling layer openings 852c in a surrounding decoupling layer 610. While exemplary large sized fulcrum connections, such as seen in FIG. 44, provide resistance to delamination some embodiment may not be as resistant to spring breakage, due the reduced cross sectional area of springs 120 where the springs 120 intersect the fulcrum connection 609.

As seen in FIGS. 40 to 45, as the fulcrum regions 852, i.e. locations of support pads 609 through the openings in the stress decoupling layer 610, e.g. comprising polyimide (PI) increase, the fulcrums 609 create an electromechanical conduit that drops, i.e. extends through the decoupling layer 610, creating the physical pad 609. The fulcrum regions 609 may comprise a wide variety of shapes, such as one or more circular pads 609, as well as elongated fulcrum regions, e.g. having a length parallel to a fixed region of a spring that is longer than the width across the fulcrum 609. Optimization of support pad design is typically influenced by promoting adequate electrical contact, as well as by providing good mechanical connections. While some support pads 609 may extend all the way across fixed traces, some such embodiments may not be desirable.

FIG. 46 and FIG. 47 are finite computer simulations illustrating the function of the stress decoupling layer 610. Finite element, i.e. grid, sizes are chosen to provide sufficient resolution in critical areas of interest. In FIG. 46, the fulcrum location 609 is undefined, and moves towards the tip 128 of the spring 120, when the spring 120 is mechanically deflected. Additionally, as the structure 970 is heated, such as during the fabrication processes or in actual use, large lateral stresses can be generated at the interface between the ceramic substrate 30 and the spring 120, due to the differences in the thermal coefficients of expansion of the substrate, e.g. typically comprising ceramic, and the spring, e.g. which typically comprises metal.

In the exemplary structural simulation 980 shown in FIG. 47, one or more fulcrum locations 609 are defined by a front support pad 609, and do not move when the spring 120 is mechanically deflected due to the compliance and hence deflection of the stress decoupling layer 610. Since the Young's modulus of the stress decoupling layer 610 is much lower than that of the ceramic substrate 30, e.g. typically greater than 10 times, e.g. the Young's modulus of Polyimide is on the order of 2.5 GPa whereas the Young's modulus of ceramic is on the order of 200 GPa, mechanical deflection of the spring 120 causes mechanical deformation of the stress decoupling layer 610.

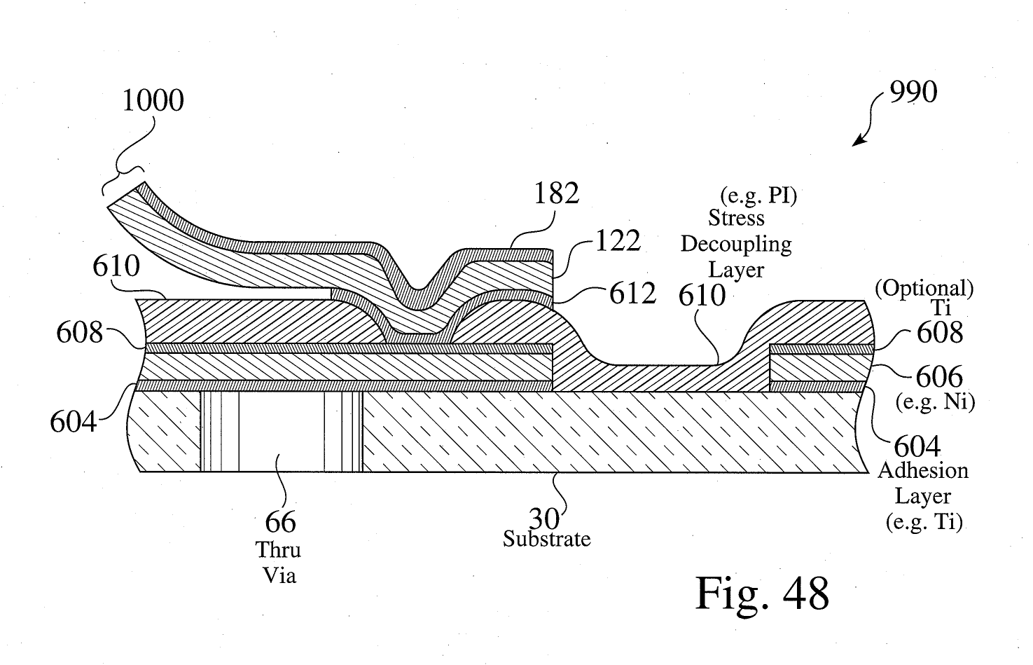

FIG. 48 shows a cross sectional view 990 of a structure comprising an unplated spring contact 1000, a stress decoupling layer 610, an electrically conductive routing layer 606 having X and Y routing capability, and a substrate 30 and an electrically conductive thru via 66. FIG. 48 also illustrates an embodiment in which layers 604, 606, and 608 have been photolithographically patterned, and the stress decoupling layer 610 is in contact with the substrate 30 in certain regions.

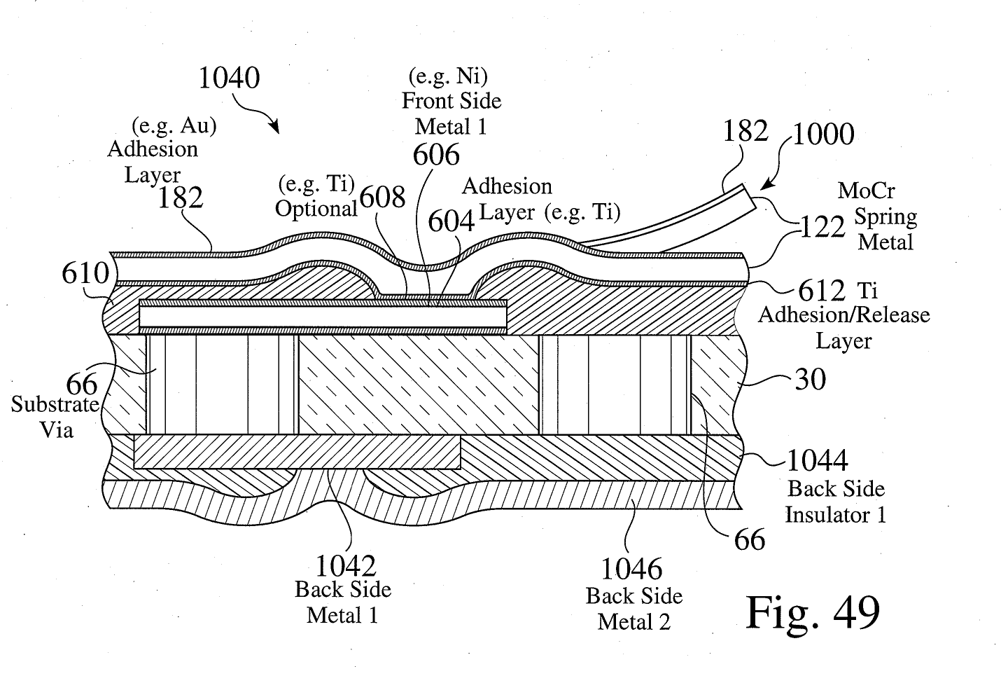

FIG. 49 shows a cross sectional view 1040 of a structure an unplated lifted spring or probe finger 1000 and associated electrically conductive routing layer 122, a front side insulating layer 610, an electrically conductive routing layer 606 having X and Y routing capability, a substrate 30 and an electrically conductive thru vias 66, a first electrically conducting routing layer 1042, a back side insulating layer 1044, and a second back side electrically conductive routing layer 1046. In one embodiment, any of back side metal layers 1042 and 1046 comprise a plated metal layers composed of any of Copper, Nickel, or Gold. Both back side routing layers 1042 and 1046 have X and Y routing capabilities. In on embodiment, any of the front and back side insulating layers 610 and 1044 comprise polyimide.

In addition, lateral stresses generated by heating, cooling and/or spring deflection are relieved by the stress decoupling layer 610. In embodiments where the stress decoupling layer 610 is formed from a polymer, e.g. polyimide, the structure is capable of withstanding spring fabrication temperature cycles, as well as most extreme temperatures encountered in the use case, e.g. −100 C to +350 C.

The disclosed decoupled spring and contactor structures provide numerous improvements, such as for providing improvement in any of fine pitch probing, cost reduction, increased reliability, and/or higher processing yields. For example, electrical contact between the spring probe structures, e.g. springs 120,122 and the substrate via structures, e.g. 66, is controllably defined with formed fulcrum region 609.

Decoupled spring and contactor structures may therefore provide improved process temperature performance and adhesion margin. As well, key parameters are decoupled in decoupled spring and contactor structures, whereby design parameters may be independently optimized. As well, Decoupled spring and contactor structures may readily be modeled and tested, provide advantages in scalability.

In some embodiments of the enhanced sputtered film processing system 10 and method 150, measurement and/or compensation are provided for any of the lift height 262 and the X-Y position of photolithographically patterned spring contacts 246. For example, any of the spring length and angle may preferably be measured and/or adjusted on the photolithographic mask to compensate for any errors, e.g. dimensional or positional, measured in produced spring substrate assemblies.

While some embodiments of the microfabricated spring contact and decoupling structures and methods are implemented for the fabrication of photolithographically patterned springs, the structures and methods may alternately be used for a wide variety of connection environments, such as to provide mechanical compliance and/or electrical connections between any of contacts, connectors, and/or devices or assemblies, over a wide variety of processing and operating conditions.

Accordingly, although the invention has been described in detail with reference to a particular preferred embodiment, persons possessing ordinary skill in the art to which this invention pertains will appreciate that various modifications and enhancements may be made without departing from the spirit and scope of the claims that follow.

1. A process, comprising the steps of:
providing a work piece comprising
a substrate having a front surface and a back surface, and
a plurality of elastic core members, each elastic core member having an anchor portion attached to the front surface of the substrate and a free portion extending away from the front surface of the substrate;
electrodepositing one or more metal coating layers enveloping the exposed surfaces of each of the respective elastic core members to provide a predetermined force thereby resulting in a predetermined value of electrical contact resistance; and
heating the plurality of elastic core members to a predetermined temperature for a predetermined time to provide increased resistance to any of set and cracking through repeated cycles of deflection of the elastic core members.

2. The process of claim 1, wherein the heating step establishes a grain size of between about 400 and about 1000 nm within the one or more electrodeposited metal coating layers.

3. The process of claim 1, further comprising the steps of:
constraining the tips of the plurality of elastic core members by a mechanical fixture at a fixed distance from either the front or the back surface of the substrate; and
subjecting the elastic core members to a controlled temperature cycle for plastic deformation of each of the elastic core members.

4. The process of claim 1, wherein the heating step comprises a ramp up time ranging from about 15 minutes to about 2 hours, a dwell time of about 10 minutes to about 2 hours depending on the planarization temperature which ranges from about 180 degrees C. to about 300 degrees C. or preferably from about 185 degrees C. to about 275 degrees C., and a ramp down time of about 15 minutes to about 6 hours.

5. The process of claim 1, wherein the at least one of the coating layers comprises any of a characteristic and a thickness sufficient to impart a force ranging from about 0.5 gram to about 15 grams at wafer prober overdrives ranging from about 15 microns to about 100 microns.

6. The process of claim 1, wherein the heating step comprises
a ramp up time ranging from about 15 minutes to about 2 hours,
a dwell time ranging from about 10 minutes to about 60 minutes, and
a ramp down time of about 15 minutes to 6 hours.

7. The process of claim 1, wherein the one or more coating layers are continuous layers deposited without a mask by supplying plating current from the back of the substrate through a via contact through the substrate.

8. The process of claim 1, wherein the at least one of the at least one coating layer covers at least a portion of the spring contact tip extending from the tip toward the anchor portion.

9. The process of claim 1, wherein the at least one of the at least one coating layer is electrodeposited through a mask formed from any of spray coated photo resist, spin coated photo resist, electrodeposited photo resist.

10. The process of claim 1, wherein the elastic core member comprises a stress metal spring.

11. A microfabricated contactor, comprising:
a substrate having a front surface and a back surface, and
a plurality of elastic core members, each elastic core member having an anchor portion attached to the front surface of the substrate and a free portion extending away from the front surface of the substrate;
one or more electrodeposited metal coating layers enveloping the exposed surfaces of each of the respective elastic core members to provide a predetermined force at a predetermined deflection, thereby resulting in a predetermined value of electrical contact resistance, wherein at least one of the continuous electrodeposited metal coating layers is annealed to establish a grain size between about 400 and 1000 nm.

12. The microfabricated contactor of claim 11, wherein any of the elastic core members and the metal coating layers provide increased resistance to any of set and cracking through repeated cycles of deflection of the elastic core members.

13. The microfabricated contactor of claim 11, wherein at least one of the electrodeposited metal coating layers promotes electrical contact to electrical connection terminals of a device under test.

14. The microfabricated contactor of claim 11, wherein at least one of the electrodeposited metal coating layers minimizes changes in the tip lift height due to set and resists cracking of any of the members of the plurality of elastic core members.

15. The microfabricated contactor of claim 11, wherein at least one of the electrodeposited metal coating layers lowers the electrical resistance through the elastic core members.

16. The microfabricated contactor of claim 11, wherein at least one of the electrodeposited metal coating layers lowers electrical contact resistance to the electrical connection points of a device under test.

17. The microfabricated contactor of claim 11, wherein the at least one of the electrodeposited metal coating layers is a continuous layer and comprises a thickness of between 1 micron and 100 microns.

18. The microfabricated contactor of claim 11, wherein the at least one of the electrodeposited metal coating layers comprises any of nickel, gold, palladium, platinum, rhodium, tungsten, cobalt, iron, copper, and combination thereof.

19. The microfabricated contactor of claim 11, wherein the resultant probe has an electrical resistance through each member of the plurality of core members of less than about 2 ohms.

20. The microfabricated contactor of claim 11, wherein the resultant probe has a contact resistance of less than about 2 ohms to electrical connection points of a device under test.

21. The microfabricated contactor of claim 11, wherein the elastic core members comprise stress metal springs.

22. A process for fabricating a spring contact comprising the steps of:
providing a structure comprising a contactor substrate having a front surface and a back surface, the contactor substrate comprising at least one electrically conductive microfabricated spring contact located on and extending from the front surface of the contactor to a initial lift height relative to either the back or front surface of the contactor substrate;
electrodepositing at least one layer of metal on the at least one spring contact to provide a low electrical resistance path through the at least one spring and, a low resistance electrical contact to a metal surface at a predetermined deflection of the at least one spring contact;
mounting the contactor substrate in a mechanical fixture for compressing the at least one spring contact against a reference surface to a distance from either the front surface or the back surface of the substrate, the distance determined by mechanical fixture, and thereby inducing stress into the at least one spring contact;
inducing plastic deformation within the at least one layer of electrodeposited metal using a planarization process to cause the working lift height to be determined by a mechanical fixture; and
annealing the at least one spring contact at a predetermined temperature for a predetermined time to cause grain growth and at least partial stress relief in the at least one layer of electrodeposited metal, the resulting spring contact possessing increased resistance to set while resisting cracking during repeated cycles of deflection thereby extending the useful life of the at least one spring contact.

23. The process of claim 22, wherein the at least one microfabricated spring contact comprises an anchor portion attached to the front surface of the substrate and a free portion, initially attached to the substrate, which upon release, extends to a initial lift height away from the substrate.

24. The process of claim 22, wherein the mechanical fixture determines the spring compression distance from the substrate using any of a fixed or adjustable spacer, a shim, a stencil, a fabricated mechanical reference, one or more screws and any combination thereof.

25. The process of claim 22, wherein at least one of the electrodeposited metal layers comprises a continuous layer of metal.

26. A spring contact made in accordance with claim 22.

27. A system, comprising:
a structure comprising a contactor substrate having a front surface and a back surface and a plurality of electrically conductive microfabricated spring contacts attached to the front surface of the substrate at an anchor region and extending away from the front surface to a predetermined tip height relative to either the back or the front surface of the contactor substrate;
at least one continuous electrodeposited metal layer enveloping each member of the plurality of spring contacts to provide a low electrical resistance there through and a specified force at a specified deflection;
a mechanical fixture for compressing the structure to compress the plurality of spring contacts to force the spring tip heights to be essentially equal; and
a heater for heating the structure to a predetermined temperature for a predetermined time to induce plastic deformation in the plurality of spring contacts thereby minimizing variations in tip height relative to either the back or the front surface of the contactor substrate, and to provide each member of the plurality of spring contacts with increased resistance to set and cracking through repeated cycles of deflection thereby extending the useful life of each member of the plurality of spring contacts.

28. The system of claim 27, wherein the at least one of the at least one continuous electrodeposited metal layers comprises a continuous metal layer that envelopes all exposed surfaces of the underlying spring contact.

29. The system of claim 27, wherein the at least one of the at least one continuous electrodeposited metal layers is deposited without a mask by supplying plating current from the back of the substrate through a via contact through the substrate.

30. The system of claim 27, further comprising at least one electrodeposited metal layer covering at least a portion of each member of the plurality of spring contacts, extending from the spring contact tip toward the anchor region to provide a robust low resistance electrical connection to the device connection terminals.

31. The system of claim 27, wherein the at least one electrodeposited metal layer is electrodeposited through a mask, the mask formed from any of spray coated photo resist, spin coated photo resist, and electrodeposited photo resist.

32. The system of claim 27, wherein each member of the plurality of electrically conductive microfabricated spring contacts is attached to the substrate at an anchor portion and comprises a free portion, initially attached to the substrate, which upon release, extends to an initial lift height away from the substrate.

33. A microfabricated spring contactor, comprising:
a structure comprising a contactor substrate having a front surface and a back surface and a plurality of electrically conductive microfabricated spring contacts attached to the front surface of the substrate at an anchor region and extending away from the front surface to a nominal tip height relative to either the back or the front surface of the contactor substrate;
a first electrodeposited metal layer enveloping each member of the plurality of spring contacts, the first electrodeposited metal layer being heated at least once to a predetermined temperature for a predetermined time with an applied stress to plastically deform the spring contacts to a fixed distance from either the front or the back surface of the substrate thereby improving the planarity of each member of the plurality of spring contact tips relative to the contactor substrate.

34. The microfabricated spring contactor of claim 33, further comprising:
a second electrodeposited metal layer enveloping the first metal layer to increase the spring constant of the spring contacts.

35. The microfabricated spring contactor of claim 34, wherein the contactor is annealed at a predetermined temperature for a predetermined time to optimize the resistance to set and cracking and over the useful life of each member of the plurality of spring contacts.

36. The microfabricated spring contactor of claim 34, further comprising:
a third electrodeposited metal layer enveloping the second metal layer, the third layer extending from the spring contact tip toward the anchor region thereby covering at least a portion of each member of the plurality of spring contacts to provide a robust low resistance electrical connection with minimized damage to the device connection terminals.

37. A microfabricated spring contactor comprising:
a structure comprising a contactor substrate having a front surface and a back surface and a plurality of electrically conductive microfabricated spring contacts attached to the front surface of the substrate at an anchor region and extending away from the front surface to a nominal tip height relative to either the back or the front surface of the contactor substrate;
a first electrodeposited metal layer enveloping each member of the plurality of spring contacts for imparting a first set of predetermined performance characteristics to each member of the plurality of spring contacts;
at least a second electrodeposited metal layer enveloping the first metal layer for imparting a second set of predetermined performance characteristics to each member of the plurality of spring contacts.

38. The microfabricated spring contactor of claim 37, wherein any of the first set and the second set of predetermined performance characteristics comprises any of improved adhesion, improved planarity, resistance to set, resistance to cracking, increased elastic modulus, improved tensile strength, improved ability to accept and retain plastic deformation, reduced electrical resistance, reduced damage to the connection terminals of a device under test, reduced tip wear, reduced electrical contact resistance, and combinations thereof.
